(19) United States
(12) Patent Application Publication
(10) Pub. No.: US 2025/0364520 A1
(43) Pub. Date: Nov. 27, 2025

(54) COMPOSITE MODULE UNIT AND SYSTEM SUBSTRATE

(71) Applicants: FLOSFIA INC, Kyoto (JP); MITSUBISHI HEAVY INDUSTRIES, LTD., Tokyo (JP)

(72) Inventors: Daisuke ASA, Tokyo (JP); Masato ITO, Tokyo (JP); Shota OKUBO, Tokyo (JP); Masaya MITAKE, Tokyo (JP); Kengo TAKEUCHI, Kyoto (JP); Tatsuhiro NAKAZAWA, Kyoto (JP); Hiroshi KONDO, Kyoto (JP); Hirofumi KOMIYA, Kyoto (JP); Toshimi HITORA, Kyoto (JP)

(21) Appl. No.: 19/295,210

(22) Filed: Aug. 8, 2025

Related U.S. Application Data
(63) Continuation-in-part of application No. PCT/JP2024/004436, filed on Feb. 8, 2024.

(30) Foreign Application Priority Data
Feb. 9, 2023 (JP) 2023-018291

(51) Int. Cl. H01L 25/18; H01L 23/36

(52) U.S. Cl. CPC H01L 25/18; H01L 23/36

(57) ABSTRACT

Provided is a composite module unit including, a first module unit including a first wiring substrate and a first power element-embedded substrate mounted on the first wiring substrate; and a second module unit including a second wiring substrate and a
second power element-embedded substrate mounted on the second wiring substrate, the first module unit and the second module unit being stacked in a thickness direction of
the first wiring substrate and the second wiring substrate, and being thermally connected to each other via a heat dissipation member.

### CROSS REFERENCE TO RELATED APPLICATION

This application is a continuation-in-part application of International Patent Application No. PCT/JP2024/004436 (Filed on Feb. 8, 2024), which claims the benefit of priority from Japanese Patent Application No. 2023-018291 (filed on Feb. 9, 2023).

The entire contents of the above applications, which the present application is based on, are incorporated herein by reference.

### 1. Field of the Invention

The present disclosure relates to a composite module unit including a wiring substrate and a power element-embedded substrate.

### 2. Description of the Related Art

A power conversion device is known to include a first substrate, a second substrate longitudinally provided on the first substrate, an electronic component disposed on a surface on one side of the second substrate in a plate thickness direction, and a heat sink disposed along the second substrate on the one side.

It should be noted that the Background Art section is intended to provide embodiments of the present disclosure in a technical or operational context to aid those skilled in the art in understanding the scope and usefulness of the present disclosure. No description disclosed herein is considered prior art merely because it is included in the Background Art section unless it is expressly identified as such.

### SUMMARY OF THE INVENTION

The following presents a simplified summary of the disclosure, which is intended to provide a basic understanding to those skilled in the art. This summary is not intended to identify key elements of the embodiments disclosed herein or to delineate the scope thereof. This summary presents some of the concepts disclosed herein in a simplified form, which serves as a prelude to the more detailed description presented later.

According to an example of the present disclosure, there is provided a composite module unit including, a first module unit including a first wiring substrate and a first power element-embedded substrate mounted on the first wiring substrate; and a second module unit including a second wiring substrate and a second power element-embedded substrate mounted on the second wiring substrate, the first module unit and the second module unit being stacked in a thickness direction of the first wiring substrate and the second wiring substrate, and being thermally connected to each other via a heat dissipation member.

According to an example of the present disclosure, there is provided a composite module unit including, a first module unit including a first wiring substrate and a first power element-embedded substrate mounted on the first wiring substrate; and a second module unit including a second wiring substrate and a second power element-embedded substrate mounted on the second wiring substrate, the first module unit and the second module unit being stacked in a thickness direction of the first wiring substrate and the second wiring substrate, the composite module unit further including a first heat dissipation member disposed on the first module unit, and a second heat dissipation member disposed along a side surface of the first module unit and a side surface of the second module unit, the first heat dissipation member and the second heat dissipation member being thermally connected to each other.

Thus, the composite module unit according to the present disclosure may exhibit improved warpage suppression and heat dissipation.

### BRIEF DESCRIPTION OF THE DRAWINGS

FIG. 1 is an exploded perspective diagram schematically illustrating a composite module unit according to a first embodiment.

FIG. 2 is a cross-sectional diagram schematically illustrating the composite module unit according to the first embodiment.

FIG. 3 is an equivalent circuit diagram of a semiconductor circuit including a power element according to the first embodiment.

FIG. 4 is a cross-sectional diagram schematically illustrating an example of a power element-embedded substrate according to the first embodiment.

FIG. 5 is a cross-sectional diagram schematically illustrating a method of fixing the composite module unit according to the first embodiment.

FIG. 6A is a cross-sectional diagram schematically illustrating a system substrate on which the composite module unit according to the first embodiment is mounted.

FIG. 6B is a top view diagram schematically illustrating a system substrate on which the composite module unit according to the first embodiment is mounted.

FIG. 7 is a cross-sectional diagram schematically illustrating the system substrate on which the composite module unit according to the first embodiment is mounted.

FIG. 8 is an exploded perspective diagram schematically illustrating a composite module unit according to a second embodiment.

FIG. 9 is a cross-sectional diagram schematically illustrating the composite module unit according to the second embodiment.

FIG. 10 is an exploded perspective diagram schematically illustrating a composite module unit according to a third embodiment.

FIG. 11 is a cross-sectional diagram schematically illustrating the composite module unit according to the third embodiment.

FIG. 12 is a perspective diagram schematically illustrating a composite module unit according to a modified example 1.

FIG. 13 is a perspective diagram schematically illustrating a composite module unit according to a modified example 2.

FIG. 14 is a perspective diagram schematically illustrating a composite module unit according to a modified example 3.

FIG. 15 is a perspective diagram schematically illustrating a composite module unit according to a modified example 4.

FIG. 16 is a block diagram illustrating an example of a control system applying a composite module unit according to an embodiment of the disclosure.

FIG. 17 is a circuit diagram illustrating an example of the control system applying a composite module unit according to an embodiment of the disclosure.

FIG. 18 is a block configuration diagram illustrating another example of the control system applying a composite module unit according to an embodiment of the disclosure.

FIG. 19 is a circuit diagram illustrating another example of the control system applying a composite module unit according to an embodiment of the disclosure.

FIG. 20 is a top view diagram schematically illustrating a composite module unit according to a modified example 5.

FIG. 21A is a cross-sectional diagram taken along the lines A-A of FIG. 20, which schematically illustrates the composite module unit according to a modified example 5.

FIG. 21B is a cross-sectional diagram taken along the lines B-B of FIG. 20, which schematically illustrates the composite module unit according to a modified example 5.

FIG. 21C is a cross-sectional diagram taken along the lines C-C of FIG. 20, which schematically illustrates the composite module unit according to a modified example 5.

FIG. 21D is a cross-sectional diagram taken along the lines D-D of FIG. 20, which schematically illustrates the composite module unit according to a modified example 5.

FIG. 22 is an exploded perspective diagram schematically illustrating the composite module unit according to the modified example 5.

FIG. 23 is a top view diagram schematically illustrating a composite module unit according to a modified example 6.

FIG. 24A is a cross-sectional diagram taken along the lines A-A of FIG. 23, which schematically illustrates the composite module unit according to a modified example 6.

FIG. 24B is a cross-sectional diagram taken along the lines B-B of FIG. 23, which schematically illustrates the composite module unit according to a modified example 6.

FIG. 24C is a cross-sectional diagram taken along the lines C-C of FIG. 23, which schematically illustrates the composite module unit according to a modified example 6.

FIG. 24D is a cross-sectional diagram taken along the lines D-D of FIG. 23, which schematically illustrates the composite module unit according to a modified example 6.

FIG. 25 is a cross-sectional diagram schematically illustrating an electronic device in which a module unit is mounted on a mounting substrate.

FIG. 26 is an exploded perspective diagram schematically illustrating the electronic device in which the module unit is mounted on the mounting substrate.

FIG. 27 is a cross-sectional diagram schematically illustrating a composite module unit according to a modified example 7.

FIG. 28 is a top view diagram schematically illustrating a composite module unit according to a modified example 8.

FIG. 29A is a cross-sectional diagram taken along the lines A-A of FIG. 28, which schematically illustrates the composite module unit according to the modified example 8.

FIG. 29B is a cross-sectional diagram taken along the lines B-B of FIG. 28, which schematically illustrates the composite module unit according to the modified example 8.

FIG. 29C is a cross-sectional diagram taken along the lines C-C of FIG. 28, which schematically illustrates the composite module unit according to the modified example 8.

FIG. 29D is a cross-sectional diagram taken along the lines D-D of FIG. 28, which schematically illustrates the composite module unit according to the modified example 8.

### DETAILED DESCRIPTION

The aspects of the present disclosure and the various features and advantageous details thereof will be explained more fully with reference to the non-limiting aspects and examples described and/or illustrated in the accompanying drawings and detailed in the following description. It should be noted that the features illustrated in the drawings are not necessarily drawn to scale, as those skilled in the art would recognize, even if not explicitly stated herein. Also, it should be noted that one feature in one aspect may be employed alone or in combination with other features in other aspects. Descriptions of well-known components and processing techniques may be omitted so as to not unnecessarily obscure the aspects of the present disclosure. The examples used herein are intended merely to facilitate an understanding of ways in which the present disclosure may be practiced and to further enable those skilled in the art to practice the aspects of the present disclosure. Accordingly, the examples and aspects herein should not be construed as limiting the scope of the present disclosure, which is defined solely by the appended claims and the applicable law. Furthermore, similar reference numerals represent similar parts throughout the drawings disclosed herein.

The terms “first”, “second”, and the like may be used herein to describe various elements, but these elements should not be limited by these terms. These terms “first”, “second”, and the like are merely used to distinguish one element from another. For example, a first element may be termed a second element, and, similarly, a second element may be termed a first element, without departing from the scope of the present disclosure. As used herein, the term “and/or” includes any or all combinations of one or more of the associated listed items.

It should be understood that when an element such as a layer, region, or substrate is referred to as being “on” or extending “onto” another element, it may be directly on or extend directly onto the other element or an intervening element may also be present. In contrast, when an element is referred to as being “directly on” or extending “directly onto” another element, there is no intervening element present. Similarly, it should be understood that when an element such as a layer, region, or substrate is referred to as being “over” or extending “over” another element, it may be directly over or extend directly over the other element or an intervening element may also be present. In contrast, when an element is referred to as being “directly over” or extending “directly over” another element, there is no intervening element present. It should also be understood that when an element is referred to as being “connected” or “coupled” to another element, it may be directly connected or coupled to the other element or an intervening element may be present. In contrast, when an element is referred to as being “directly connected” or “directly coupled” to another element, there is no intervening element present. Furthermore, it should be understood that when an element is referred to as being “stacked” on another element, it may be directly stacked on the other element or an intervening element may be present. In contrast, when an element is referred to as being “directly stacked” on another element, there is no intervening element present.

The terminology used herein is for the purpose of describing particular aspects only and is not intended to be limiting of the present disclosure. It should be understood that the terms “comprise (or comprising)” or “include (or including)” specify the presence of stated elements, but do not preclude the presence of one or more other elements.

Unless otherwise defined, all terms (including technical and scientific terms) used herein have the same meaning as commonly understood by those skilled in the art to which the present disclosure belongs. Terms used herein should be interpreted as having a meaning that is consistent with their meaning in the context of this specification and the relevant art. It should be further understood that terms used herein should not be interpreted in an idealized or overly formal sense unless expressly defined so herein.

In the present disclosure, unless otherwise defined, a stacking direction of a wiring substrate (direction perpendicular to the wiring substrate surface) is described as the Y direction, and a stacking direction of a mounting substrate (direction perpendicular to the mounting substrate surface) is described as the Z direction. Moreover, in a module unit in which the power element-embedded substrate is mounted on a first surface side of the wiring substrate, “top (or upper or above)” is defined as an upper side which is the power element-embedded substrate side when viewed from the wiring substrate, and “bottom (or lower or below)” is defined as the lower side which is the wiring substrate side when viewed from the power element-embedded substrate. In the case of a structure in which the power element-embedded substrates are mounted on both sides of the wiring substrate, a separate definition is required. Moreover, in an electronic device, “top (or upper or above)” is defined as an upper side which is the module unit side as viewed from the mounting substrate, and “bottom (or lower or below)” is defined as the lower side which is the mounting substrate side as viewed from the module unit side. In this specification, a top view may be rephrased as a plan view.

A composite module unit in one aspect disclosed herein is characterized as including: a first module unit including a first wiring substrate and a first power element-embedded substrate mounted on the first wiring substrate; and a second module unit including a second wiring substrate and a second power element-embedded substrate mounted on the second wiring substrate, the first module unit and the second module unit being stacked in a thickness direction of the first wiring substrate and the second wiring substrate, and being thermally connected to each other via a heat dissipation member. Moreover, a composite module unit in another aspect disclosed herein is characterized as including: a first module unit including a first wiring substrate and a first power element-embedded substrate mounted on the first wiring substrate; and a second module unit including a second wiring substrate and a second power element-embedded substrate mounted on the second wiring substrate, the first module unit and the second module unit being stacked in a thickness direction of the first wiring substrate and the second wiring substrate, the composite module unit further including a first heat dissipation member disposed on the first module unit, and a second heat dissipation member disposed along a side surface of the first module unit and a side surface of the second module unit, the first heat dissipation member and the second heat dissipation member being thermally connected to each other.

### First Embodiment

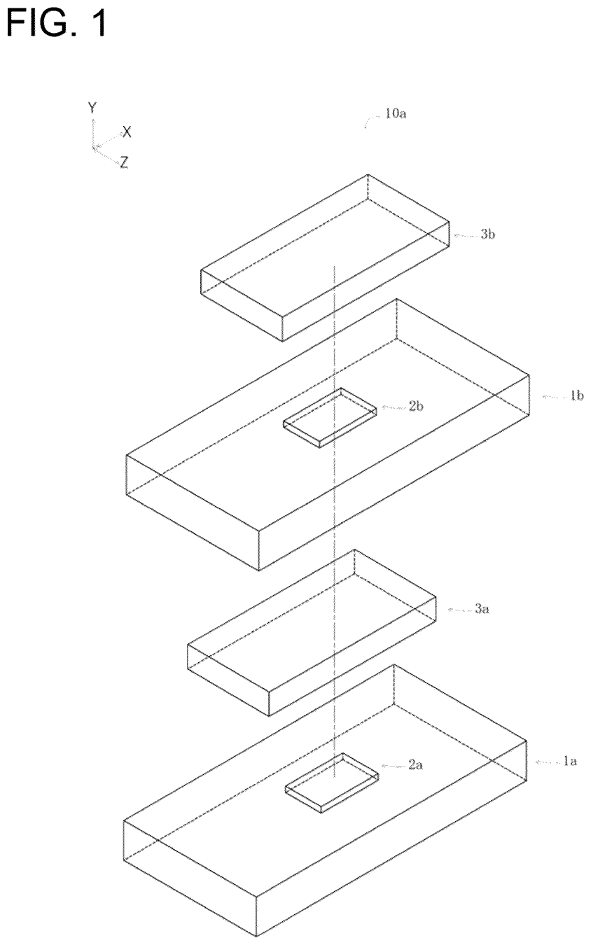

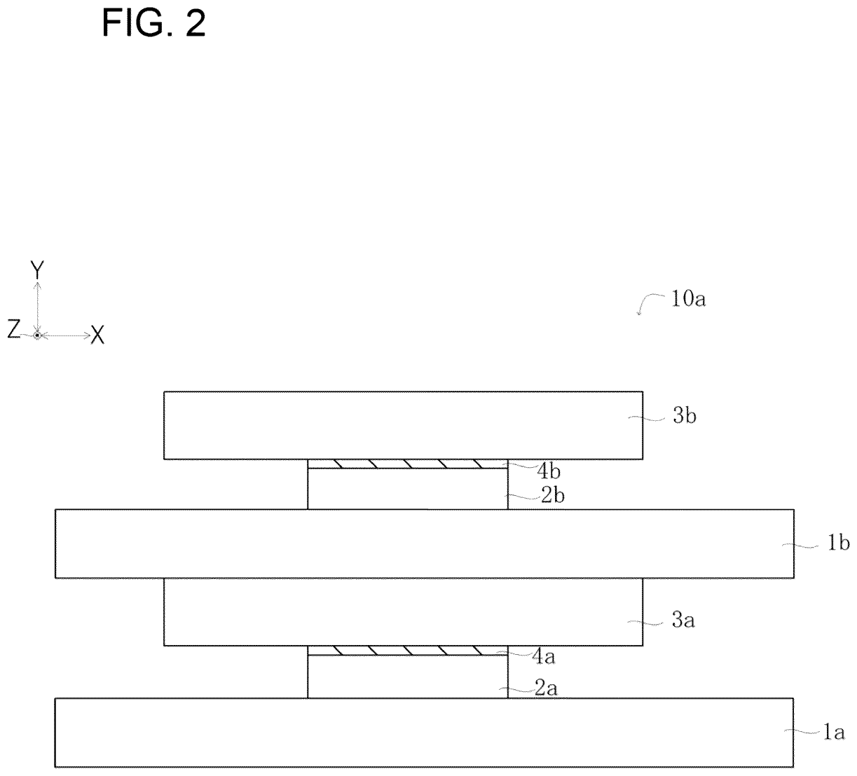

FIG. 1 is a schematical exploded perspective diagram illustrating a composite module unit 10a according to a first embodiment. FIG. 2 is a schematic cross-sectional diagram of the composite module unit 10a, illustrating a cross section of the composite module unit 10a illustrated in FIG. 1 taken along a stacking direction (Y direction). In the composite module unit 10a illustrated in FIGS. 1 and 2, a first wiring substrate 1a, a first power element-embedded substrate 2a, a first heat dissipation member 3a, a second wiring substrate 1b, a second power element-embedded substrate 2b, and a second heat dissipation member 3b are stacked in this order. The first wiring substrate 1a, the first power element-embedded substrate 2a, and the first heat dissipation member 3a constitute a first module unit, and the second wiring substrate 1b, the second power element-embedded substrate 2b, and the second heat dissipation member 3b constitute a second module unit. Although not illustrated in FIG. 1, an insulating member 4a may be disposed between the first heat dissipation member 3a and the first power element-embedded substrate 2a, and insulating member 4b may be disposed between the second heat dissipation member 3b and the second power element-embedded substrate 2b. In the composite module unit of the present disclosure, the insulating members 4a and 4b are not essential; and at least a portion of the first heat dissipation member 3a and at least a portion of the first power element-embedded substrate 2a may be in direct contact with each other, and at least a portion of the second heat dissipation member 3b and at least a portion of the second power element-embedded substrate 2b may be in direct contact with each other.

Moreover, in the present embodiment, two module units including the first module unit and the second module unit are stacked, but in the present disclosure, the number of the module units to be stacked is not limited to this example. In the present disclosure, one or more module units may be further stacked on the second module unit. In FIGS. 1 and/or 2, electrical connections for the wiring substrate and power element-embedded substrate are not illustrated, but each connection may be realized using a well-known method. Moreover, the first wiring substrate 1a, the first power element-embedded substrate 2a, the first heat dissipation member 3a, the second wiring substrate 1b, the second power element-embedded substrate 2b, and the second heat dissipation member 3b may be fixed using a known method, and details of the fixing method will be described later.

### (Wiring Substrate)

The first wiring substrate 1a and/or the second wiring substrate 1b (hereinafter, collectively referred to as “wiring substrate”) may be a dielectric substrate or may be a multilayered dielectric substrate. Moreover, the wiring substrate has a signal conductor pattern (not illustrated) wired on an upper surface and/or an inner layer. Although not illustrated, the wiring substrate 1a may have an electrode pattern or an electrode pin for connecting to a connector on the mounting substrate side for establishing electrical connection with the mounting substrate. Furthermore, a circuit component (e.g., passive component, such as a capacitor) other than the power element may be mounted on the wiring substrate 1a.

### (Power Element-Embedded Substrate)

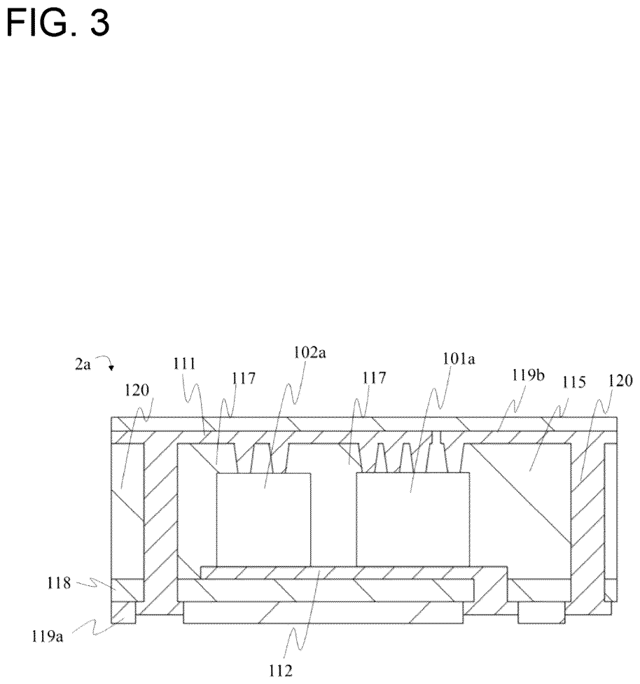

The first power element-embedded substrate 2a and/or the second power element-embedded substrate 2b (hereinafter, collectively referred to as “power element-embedded substrate”) is, for example, a multilayer wiring substrate in which a power element (diode, transistor, etc.) constituting a portion of the power conversion circuit is embedded. More specifically, for example, as illustrated in FIG. 3, the power element-embedded substrate 2a and/or 2b has a structure having an insulation layer 115 between a wiring layer (first wiring layer) 111 and a retention layer (second wiring layer) 112 so that a transistor 101a and a diode 102a as power elements are embedded in the insulation layer 115. In the power element-embedded substrate 2a illustrated in FIG. 3, the first wiring layer 111 constitutes an upper wiring layer, and the retention layer 112 constitutes a portion of the second wiring layer (lower wiring layer). The second wiring layer 112 is composed of a copper foil formed over both surfaces of a base material 118, and the copper foil on a first surface side of the base material 118 and a copper foil on a second surface side are electrically connected to each other through a through hole. Moreover, the diode 102a and the transistor 101a are placed respectively via adhesion layers (not illustrated) on the retention layer (copper foil on the first surface side) 112. The retention layer may constitute the second wiring layer, or may be composed of any other member (e.g., an insulating substrate, such as a metallic substrate or a ceramic substrate).

The diode 102a is, for example, a Schottky barrier diode (SBD), a fast recovery diode (FRD), or a PiN diode. Moreover, the transistor 101a is, for example, a metal oxide semiconductor field effect transistor (MOSFET) or an insulated gate bipolar transistor (IGBT). The semiconductor materials constituting the diode 102a and the transistor 101a as the power elements are not particularly limited. Examples of the semiconducting material include silicon, gallium nitride, silicon carbide, gallium oxide, and diamond. The power element-embedded substrate is manufactured using a known method of manufacturing a component-embedded substrate. A thickness of the power element-embedded substrate in the stacking direction (Y direction) is, for example, not more than 3 mm, or preferably not more than 1 mm. An area of the power element-embedded substrate as viewed from above is, for example, not more than 2000 mm², or preferably not more than 1000 mm².

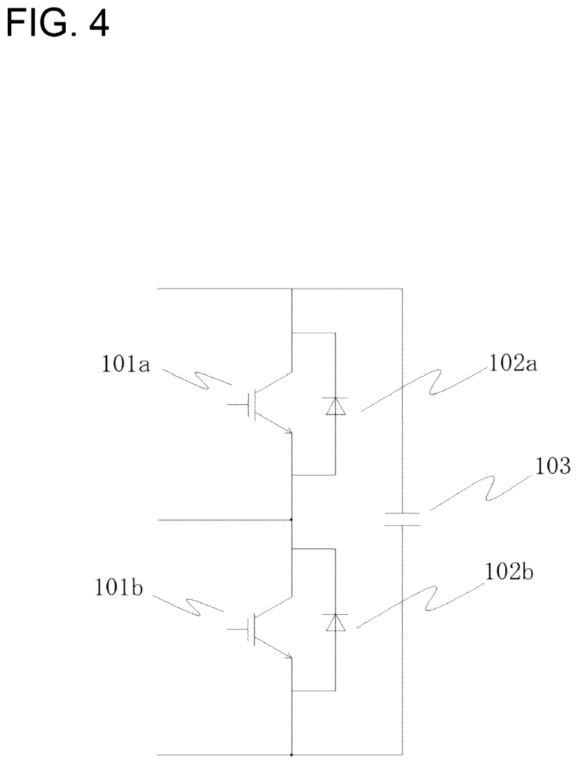

FIG. 4 is an equivalent circuit diagram for describing positioning in a circuit of a power element embedded in the power element-embedded substrate. In a circuit configuration illustrated in FIG. 4, an anti-parallel circuit of a transistor 101a and a diode 102a and an anti-parallel circuit of a transistor 101b and a diode 102b are connected in series, and a capacitor 103 is further connected in parallel to the transistors 101a and 101b. The semiconductor circuit is applied to, for example, a power conversion circuit including an inverter circuit or a converter circuit.

In the present embodiment, the first power element-embedded substrate 2a is equipped with the transistor 101a and the diode 102a in the equivalent circuit illustrated in FIG. 4. Moreover, the second power element-embedded substrate 2b is equipped with the transistor 101b and the diode 102b in the equivalent circuit illustrated in FIG. 4. In the present disclosure, the power element-embedded substrate may be equipped with a plurality of transistors (e.g., transistors 101a and 101b) and/or a plurality of diodes (e.g., diodes 102a and 102b). When the power element-embedded substrate is equipped with a plurality of transistors, the plurality of transistors may be electrically connected in series or in parallel to each other. In the present disclosure, the module unit may include a plurality of power element-embedded substrates as will be described later. It should be noted that the circuit configuration described above is merely an example, and other circuit configurations may be used. In the present disclosure, the power conversion circuit may be configured by combining a plurality of the power element-embedded substrates together with other passive components.

### (Heat Dissipation Member)

The first heat dissipation member 3a and/or the second heat dissipation member 3b (hereinafter, collectively referred to as “heat dissipation member”) are disposed in order to thermally dissipate heat generated in the power element-embedded substrate. The material constituting the heat dissipation member is not particularly limited as long as it does not hinder the object of the present disclosure. Examples of the material constituting the heat dissipation member include metal materials, ceramic materials, carbon-based materials, and composite materials thereof. In the present disclosure, the heat dissipation member is preferably a metal block. In the present disclosure, a surface side facing the power element-embedded substrate may have a recessed portion. The metal block has, for example, a rectangular shape or circular shape in a plan view. Moreover, the metal block has a larger shape than the power element-embedded substrate in a plan view. FIG. 3 illustrates an example of the metal block. The recessed portion is formed using a well-known metal processing method (punching, laser machining, cut machining, metal plating, 3D printer, etc.).

Moreover, the material constituting the metal block is not particularly limited as long as it does not hinder the object of the present disclosure. Examples of the material constituting the metal block include Cu, Au, Al, Ag, Fe, Ti, Ni, Pt, Pd, and alloys thereof (which may contain other metals or carbon, etc.). In the present disclosure, the material constituting the metal block preferably contains copper (Cu) or aluminum (Al), and more preferably contains aluminum (Al). In the present disclosure, it is preferable that the periphery of the power element-embedded substrate is covered with the recessed portion of the metal block. Moreover, a depth of the recessed portion is not particularly limited. The depth of the recessed portion is, for example, not more than 5 mm, preferably not more than 3 mm, and more preferably not more than 1 mm.

In the present disclosure, as illustrated in FIG. 2, for example, the first insulating member 4a and/or the second insulating member 4b may be disposed respectively between the first heat dissipation member 3a and the power element-embedded substrate 2a and/or between the second heat dissipation member 3b and the second power element-embedded substrate 2b. The first insulating member 4a and/or the second insulating member 4b (hereinafter, collectively referred to as “insulating member”) preferably have high thermal conductivity, and more specifically, are made of a well-known Thermal Interface Material (TIM), such as a layer of a resin such as an epoxy resin containing a filler such as boron nitride (BN), aluminum nitride (AlN), or alumina (Al₂O₃). The insulating member and the power element-embedded substrate may be bonded to each other using a well-known electrical conductivity binder or the like.

### (Example of Manufacturing Method)

Hereinafter, a method of manufacturing the composite module unit having the above-described structure will be described.

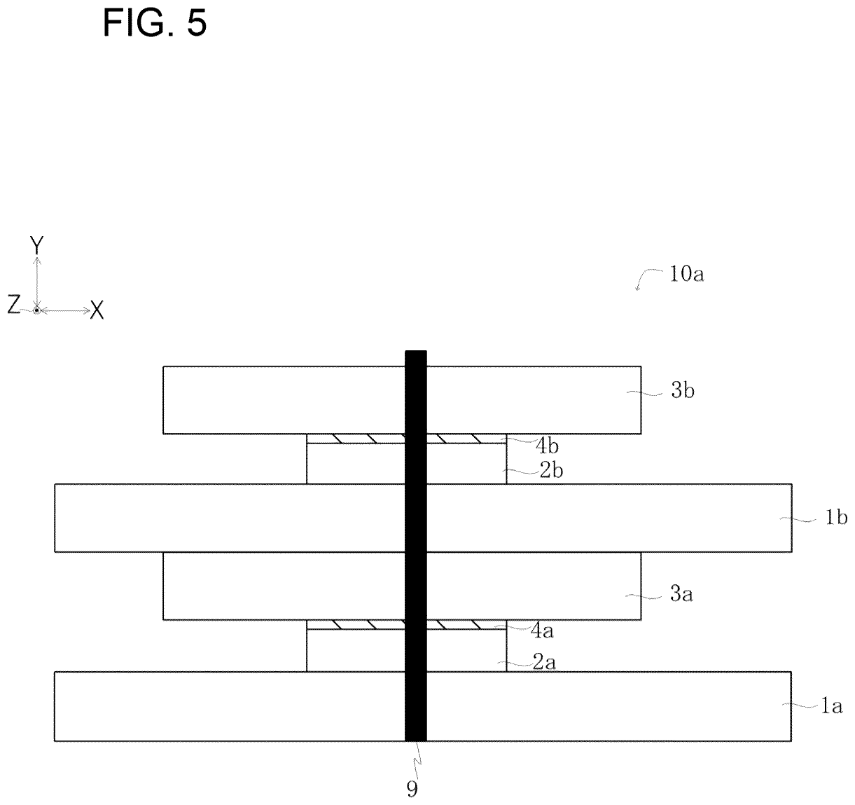

In an assembly process of the module unit, the first power element-embedded substrate 2a is connected to (mounted on) the first wiring substrate 1a by using a well-known method. Thereafter, the first heat dissipation member 3a is bonded onto the first power element-embedded substrate 2a, via the first insulating member 4a having excellent thermal conductivity as desired. Subsequently, the second wiring substrate 1b, the second power element-embedded substrate 2b, and the heat dissipation member 3b are stacked in the same manner as above. As illustrated in FIG. 5, the components are fixed to one another by screwing a screw 9 through a through-hole in the respective components. The through-hole may be formed before the above-described stacking process or may be formed after the stacking process. By fastening them with the screw in this manner, adhesion between the power element-embedded substrate and the heat dissipation member is improved, thereby providing a configuration having more excellent heat dissipation. The present embodiment illustrates an example in which the power element-embedded substrates are passed through to be screwed, but the present disclosure is not limited to this example. For example, it may be configured to fasten, with the screw, the first wiring substrate 1a, the first heat dissipation member 3a, the second wiring substrate 1b, and the second heat dissipation member 3b. Furthermore, the method of fixing each component of the composite module unit is not limited to the screw fastening, and any known method may be used. For example, a method of fixing using a busbar or a method of fixing using a clip may be used. The manufacturing method of the composite module unit described above is merely an example, and other methods may be used. For example, the assembly process of the module unit is not limited to the steps described above, and steps may be added or deleted, or the order of steps may be changed, etc., without departing from the spirit and technical concept.

### (Mounting Example on Mounting Substrate)

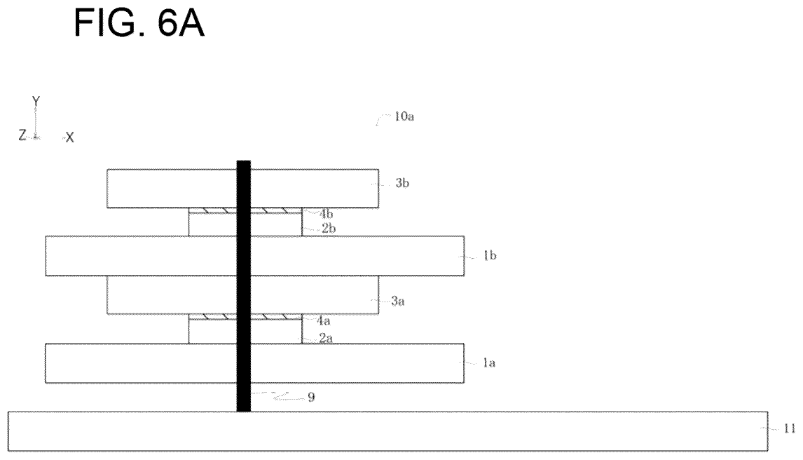

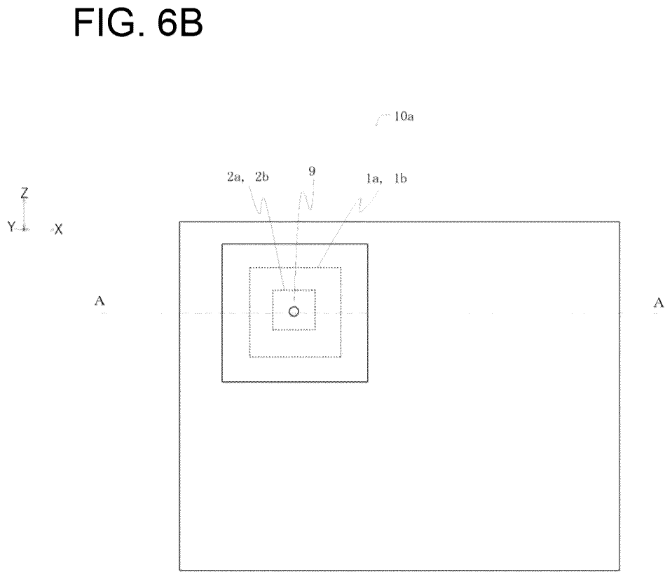

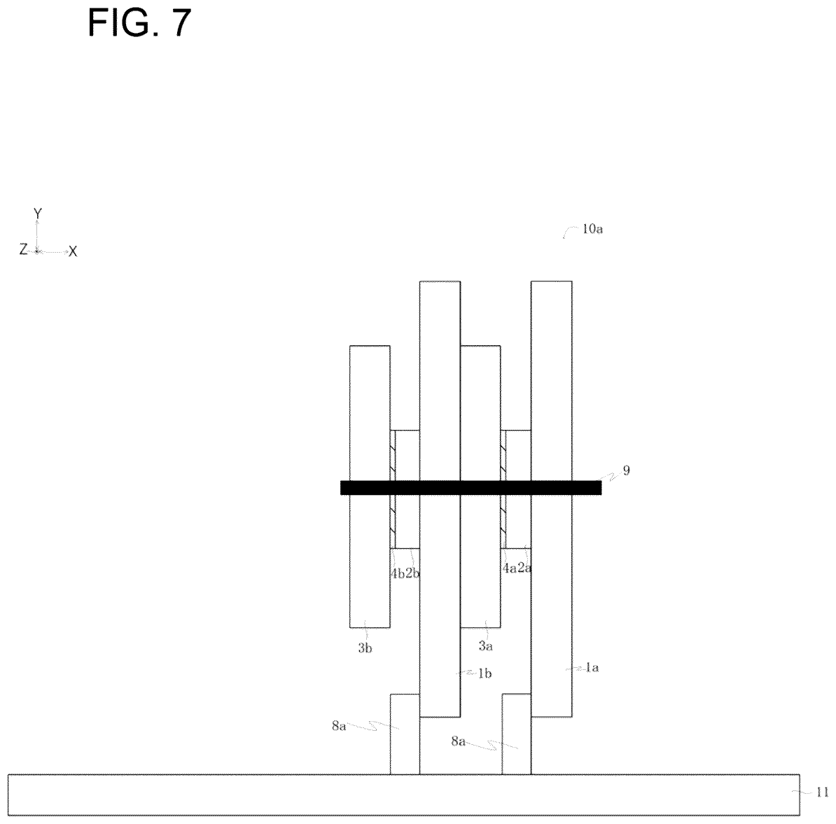

FIG. 6 illustrates an example of mounting the composite module unit 10a on the mounting substrate 11. FIG. 6A illustrates a schematic cross-sectional diagram, and FIG. 6B illustrates a schematic top view diagram. As is clear from FIGS. 6A and 6B, the composite module unit of the present embodiment is fixed onto the mounting substrate 11 with the screw 9. In FIG. 6, electrical connections for the wiring substrate, the power element-embedded substrate, and the mounting substrate are not illustrated, but these connections are realized using a well-known method. Moreover, FIG. 7 illustrates an example in which the composite module unit 10a is mounted so as to be longitudinally provided on the mounting substrate 11. As illustrated in FIG. 7, electrode pins 8a are respectively provided on the first wiring substrate 1a and the second wiring substrate 1b of the composite module unit 10a, and the electrode pins 8a are inserted into holes (not illustrated) on the mounting substrate 11 side, and thereby the first and second wiring substrates 1a and 1b are longitudinally provided to be electrically connected to the mounting substrate 11. The connection method and fixing method to the mounting substrate 11 are not limited to the example illustrated in FIGS. 6 and 7.

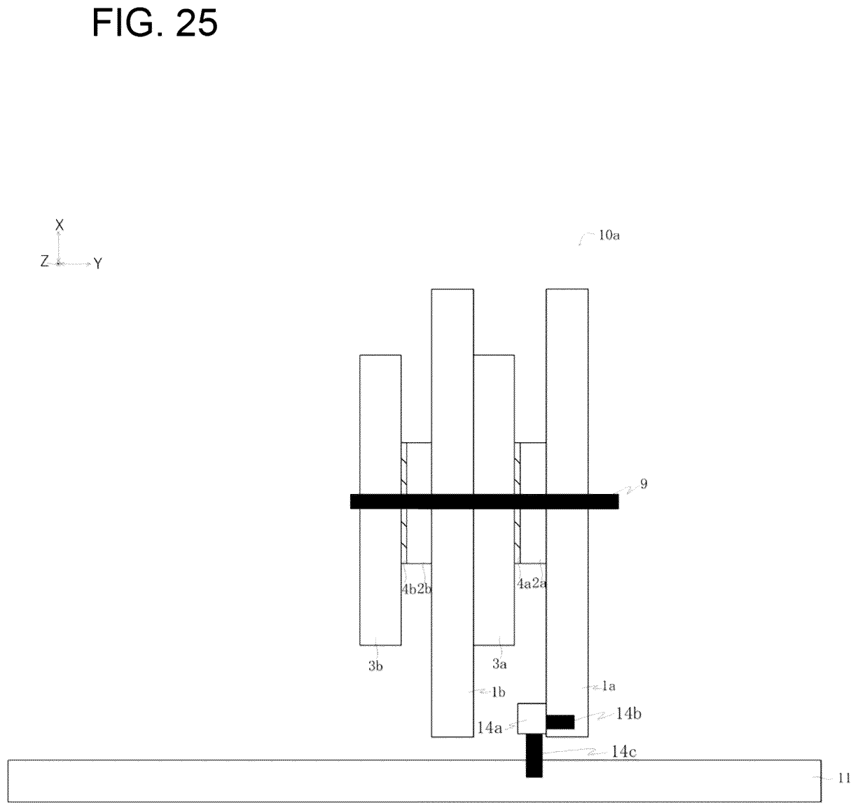

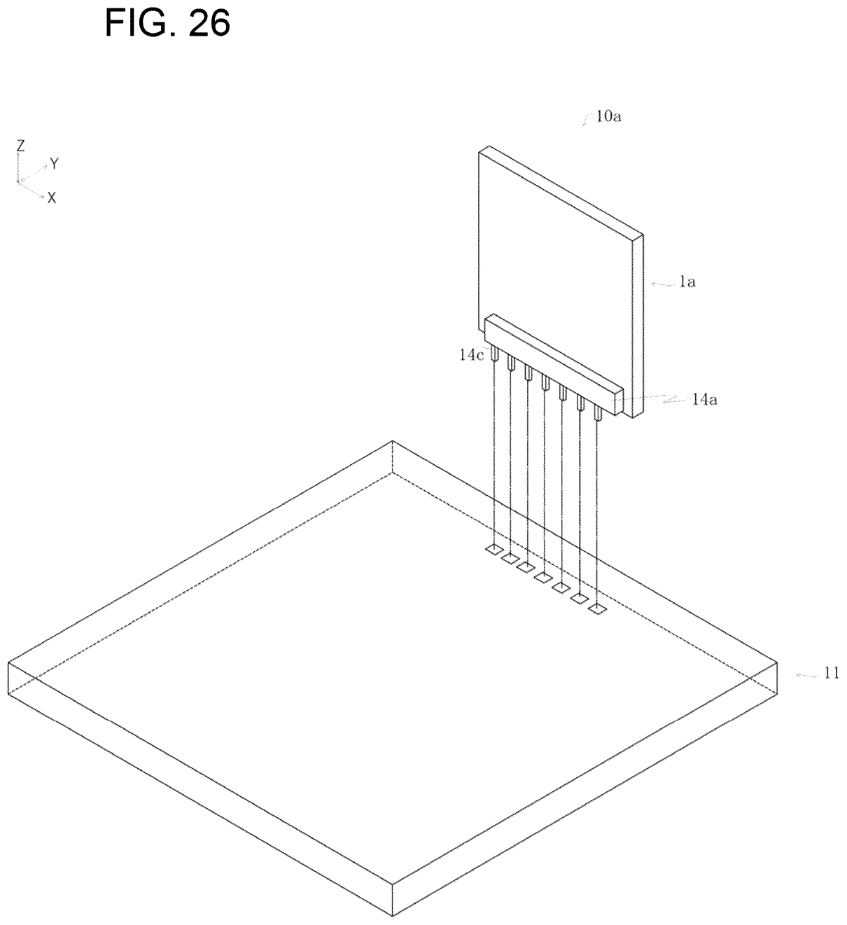

FIG. 25 illustrates another example of an electronic device in which the composite module unit 10a is longitudinally provided on the mounting substrate 11. FIG. 25 illustrates a cross-sectional diagram schematically illustrating a state where a composite module unit 10a is longitudinally provided on a mounting substrate 11, and FIG. 26 illustrates an exploded perspective diagram thereof. In the exploded perspective diagram of FIG. 26, the second module unit (the second wiring substrate 1b, the second power element-embedded substrate 2b, and the second heat dissipation member 3b), the first power element-embedded substrate 2a, the first heat dissipation member 3a, etc. are not illustrated for describing the connection portion. As illustrated in FIGS. 25 and 26, the wiring substrate 1a of the composite module unit 10a is connected to the mounting substrate 11 using a connection member including a resin portion 14a and a pin portion 14b. As illustrated in FIG. 25, the pin portion 14b extending in the Y direction so as to be connected to the first wiring substrate 1a, and the pin portion 14c extending in the X direction so as to be connected to the mounting substrate 11 are connected by being inserted into the resin portion 14a.

### Advantageous Effects of First Embodiment

As described above, in the composite module unit 10a of the present embodiment, the first module unit including the first wiring substrate 1a on which the first power element-embedded substrate is mounted, and the second module unit including the second wiring substrate 1b on which the second power element-embedded substrate is mounted are thermally connected to each other via the first heat dissipation member 3a. Therefore, it is possible to have excellent heat dissipation and to suppress warpage due to a difference in coefficients of thermal expansion. Moreover, the module unit 10a of the present embodiment has excellent handleability since the wiring substrate, the power element-embedded substrate, and the heat dissipation member (metal block) are integrated together. Furthermore, by combining a plurality of module units, it is possible to improve flexibility of implementation design of the entire power conversion circuit, for example, even without having to perform strict design of heat dissipation and noise characteristics.

### Second Embodiment

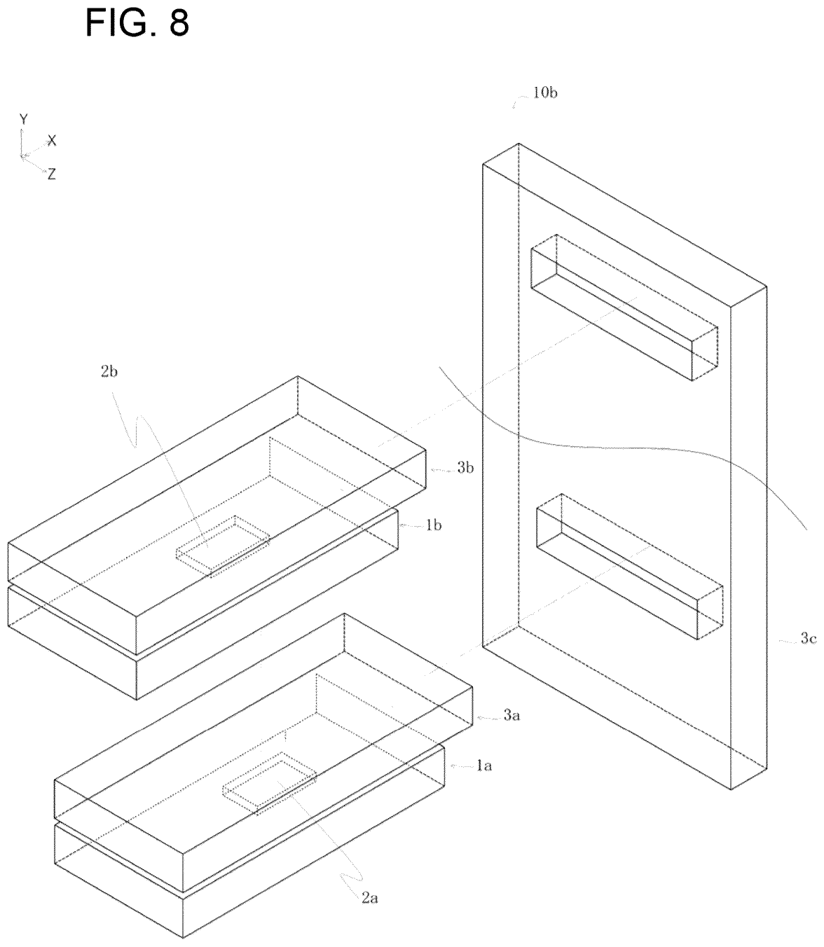

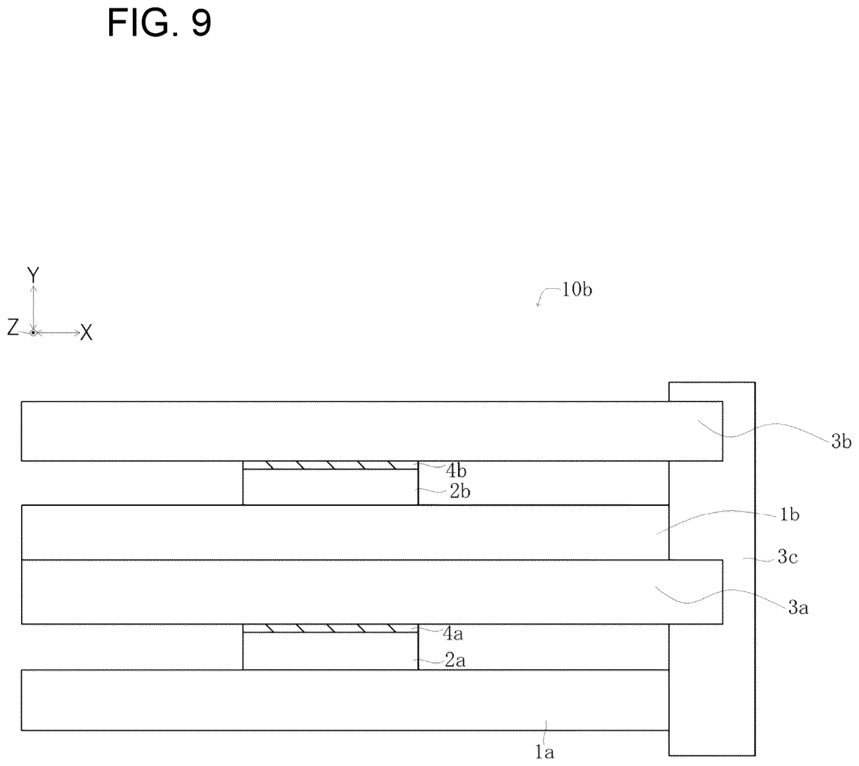

FIG. 8 is an exploded perspective diagram schematically illustrating a composite module unit 10b according to a second embodiment. FIG. 9 is a schematic cross-sectional diagram of the composite module unit 10b, illustrating a cross section of the composite module unit 10b illustrated in FIG. 8 taken along a stacking direction (Y direction). In the composite module unit 10b illustrated in FIG. 8, a first wiring substrate 1a, a first power element-embedded substrate 2a, a first heat dissipation member 3a, a second wiring substrate 1b, a second power element-embedded substrate 2b, and a second heat dissipation member 3b are stacked in this order. The first wiring substrate 1a, the first power element-embedded substrate 2a, and the first heat dissipation member 3a constitute a first power module unit, and the second wiring substrate 1b, the second power element-embedded substrate 2b, and the second heat dissipation member 3b constitute a second module unit.

The composite module unit 10b of the present disclosure includes a third heat dissipation member 3c. The third heat dissipation member 3c is disposed along the side surfaces of the first module unit and the second module unit, and the first heat dissipation members 3a and the second heat dissipation members 3b are further connected thermally to the third heat dissipation member 3c. The third heat dissipation member 3c includes recessed portions respectively corresponding to the first heat dissipation member 3a and the second heat dissipation member 3b, and at least a portion of one end of each of the first heat dissipation members 3a and 3b fits to each of the recessed portions, thereby the third heat dissipation member 3c is connected to the first and second heat dissipation members 3a and 3b. A material constituting the third heat dissipation member 3c may be the same as that of the first and second heat dissipation members 3a and 3b. The method of connecting the third heat dissipation member 3c to the first and second heat dissipation members 3a and 3b is not limited to the method illustrated in the present embodiment. The method of connecting the third heat dissipation member 3c to the first and second heat dissipation members 3a and 3b may be a well-known method including a method using a screw described below.

### Advantageous Effects of Second Embodiment

In the composite module unit 10b illustrated in FIGS. 8 and 9, the first module unit including the first wiring substrate 1a on which the first power element-embedded substrate is mounted, and the second module unit including the second wiring substrate 1b on which the second power element-embedded substrate is mounted are stacked in this order, and the first heat dissipation member 3a disposed on the first module unit is thermally connected to the third heat dissipation member 3c disposed along the side surfaces of the first module unit and the second module unit. Therefore, it is possible to have excellent heat dissipation and to suppress warpage due to a difference in coefficients of thermal expansion. Moreover, the module unit 10b of the present embodiment has excellent handleability since the wiring substrate, the power element-embedded substrate, and the heat dissipation member (metal block) are integrated together. Furthermore, by combining a plurality of module units, it is possible to improve flexibility of implementation design of the entire power conversion circuit, for example, even without having to perform strict design of heat dissipation and noise characteristics. Furthermore, in the present embodiment, since the respective wiring substrates are stacked, it is possible to further satisfactorily reduce the inductance.

### Third Embodiment

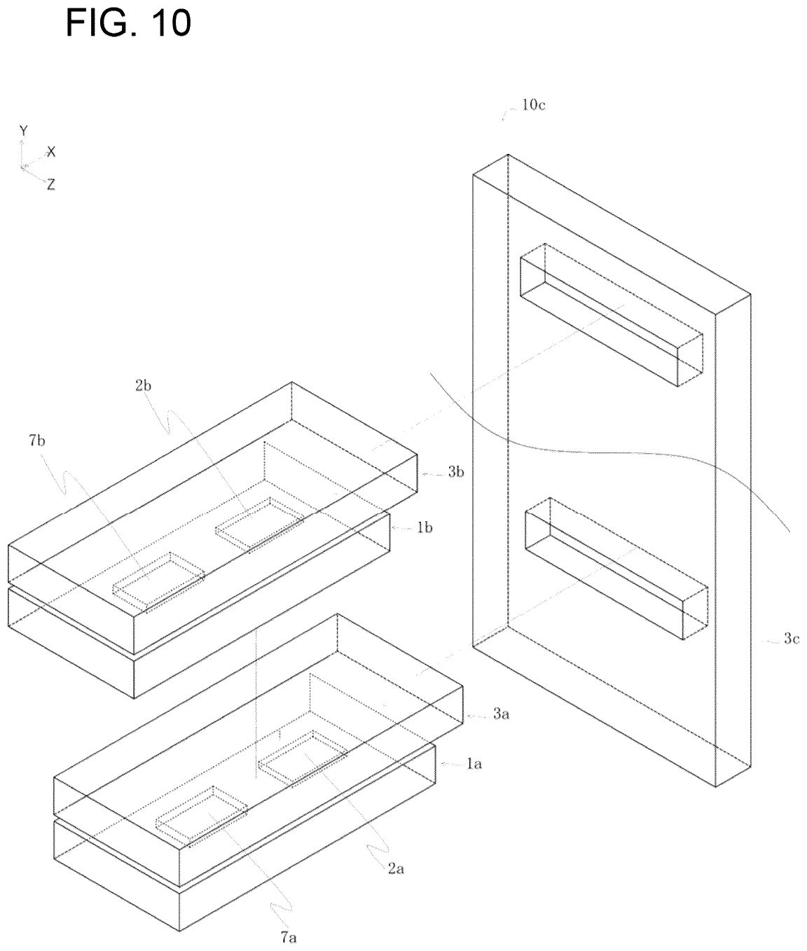

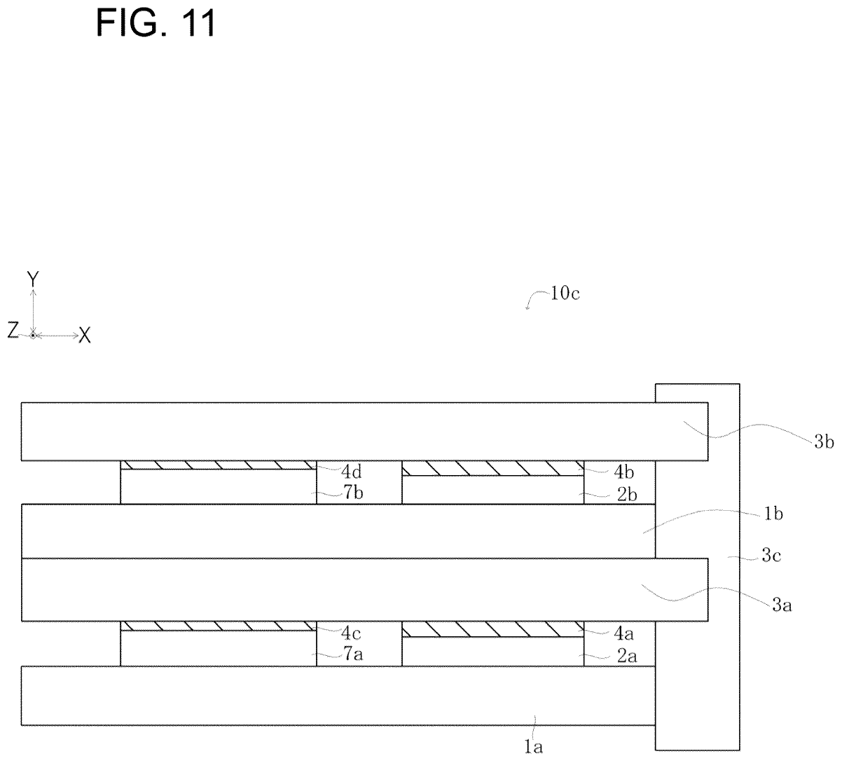

FIG. 10 is an exploded perspective diagram schematically illustrating a composite module unit 10c according to a third embodiment, and FIG. 11 is a schematic cross-sectional diagram thereof. The composite module unit illustrated in FIGS. 10 and 11 is different from the module unit 10b according to the second embodiment in the following respects: a point that a gate driver 7a controlling a switching operation of the first power element-embedded substrate 2a and a power element in the first power element-embedded substrate is disposed on the first wiring substrate 1a; and a point that a gate driver 7b controlling a switching operation of the second power element-embedded substrate 2b and a power element in the second power element-embedded substrate is disposed on the second wiring substrate 1b. The gate drivers 7a and/or 7b are each composed of an IC equipped with a drive circuit of controlling the switching operation of a gate electrode of the power element disposed in the power element-embedded substrate.

Although not illustrated in FIG. 10, as illustrated in FIG. 11, insulating members 4a and 4c may be respectively interposed between the first power element-embedded substrate 2a and the first gate driver 7a, and the first heat dissipation member 3a. Moreover, insulating members 4b and 4d may be respectively interposed between the second power element-embedded substrate 2b and the second gate driver 7b, and the second heat dissipation member 3b. In the present embodiment, for example, since a thickness of the first power element-embedded substrate 2a in the stacking direction (Y direction) is smaller than a thickness of the gate driver 7a in the stacking direction, a thickness of the insulating member 4a is set to be larger than a thickness of the insulating member 4c, in order to match the entire thicknesses. In the present embodiment, a difference between the thickness of the power element-embedded substrate and the thickness of the gate driver is absorbed with the thicknesses of the insulating members 4a (4b) and 4c (4d), but the present disclosure is not limited to this example. In the present disclosure, for example, the difference between the thickness of the power element-embedded substrate and the thickness of the gate driver may be absorbed by making the heat dissipation member into any shape.

### Advantageous Effects of Third Embodiment

According to the composite module unit 10c in FIGS. 10 and 11, since the power element-embedded substrate and the gate driver are mounted on the same wiring substrate, it is possible to further satisfactorily suppress noise, as compared with the second embodiment, in addition to the advantageous effects of the first and second embodiments. Moreover, since it is possible to configure an integrated module unit including the power element-embedded substrate and the gate driver, thereby further improving flexibility in design of the entire system.

### Modified Example 1

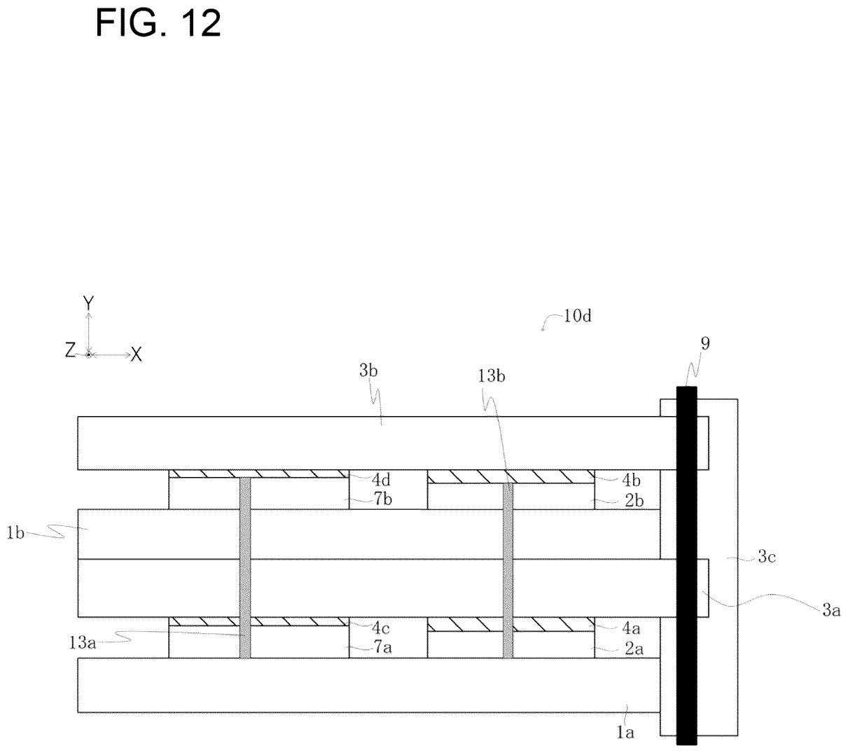

As a modified example 1, FIG. 12 illustrates one aspect of a method of fixing and electrical connecting between components of the composite module unit according to the present disclosure. In a composite module unit 10d in FIG. 12, a first module unit in which the first power element-embedded substrate 2a and the first gate driver 7a are mounted on the first wiring substrate 1a, and a second module unit in which the second power element-embedded substrate 2b and the second gate driver 7b are mounted on the second wiring substrate 1b, are stacked in a stacking direction (Y direction) of the power element-embedded substrates. Furthermore, the first heat dissipation member 3a is disposed on the first module unit, and the second heat dissipation member 3b is disposed on the second module unit. Moreover, at least a portion of the first heat dissipation member 3a and at least a portion of the second heat dissipation member 3b are fitted to the third heat dissipation member 3c. Moreover, in this modified example, the first wiring substrate 1a and the second wiring substrate 1b are electrically connected to each other with pins 13a and/or 13b respectively passing through the first gate driver 7a and the second gate driver 7b, and the first power element-embedded substrate 2a and the second power element-embedded substrate 2b. The first, second, and third heat dissipation members are fixed by a screw 9 which passes through the third heat dissipation member 3c and the first and second heat dissipation members 3a, 3b fitted to the third heat dissipation member 3c.

### Modified Example 2

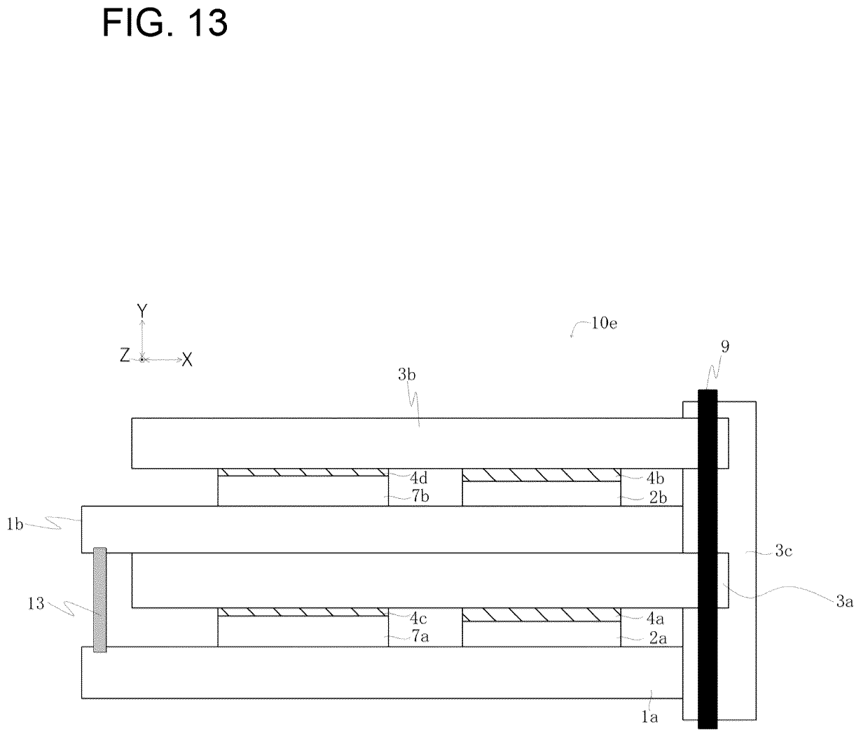

As a modified example 2, FIG. 13 illustrates one aspect of fixing and electrical connecting between the components of the composite module unit according to the present disclosure. In a composite module unit 10e illustrated in FIG. 13, a first module unit in which the first power element-embedded substrate 2a and the first gate driver 7a are mounted on the first wiring substrate 1a, and a second module unit in which the second power element-embedded substrate 2b and the second gate driver 7b are mounted on the second wiring substrate 1b, are stacked in a stacking direction (Y direction) of the power element-embedded substrates. Furthermore, the first heat dissipation member 3a is disposed on the first module unit, and the second heat dissipation member 3b is disposed on the second module unit. Moreover, at least a portion of the first heat dissipation member 3a and at least a portion of the second heat dissipation member 3b are fitted to the third heat dissipation member 3c. Moreover, in this modified example, the first wiring substrate 1a and the second wiring substrate 1b are electrically connected to each other with a pin 13. Moreover, the first, second, and third heat dissipation members are fixed by a screw 9 which passes through the third heat dissipation member 3c and the first and second heat dissipation members 3a, 3b fitted to the third heat dissipation member 3c.

### Modified Examples 3 and 4

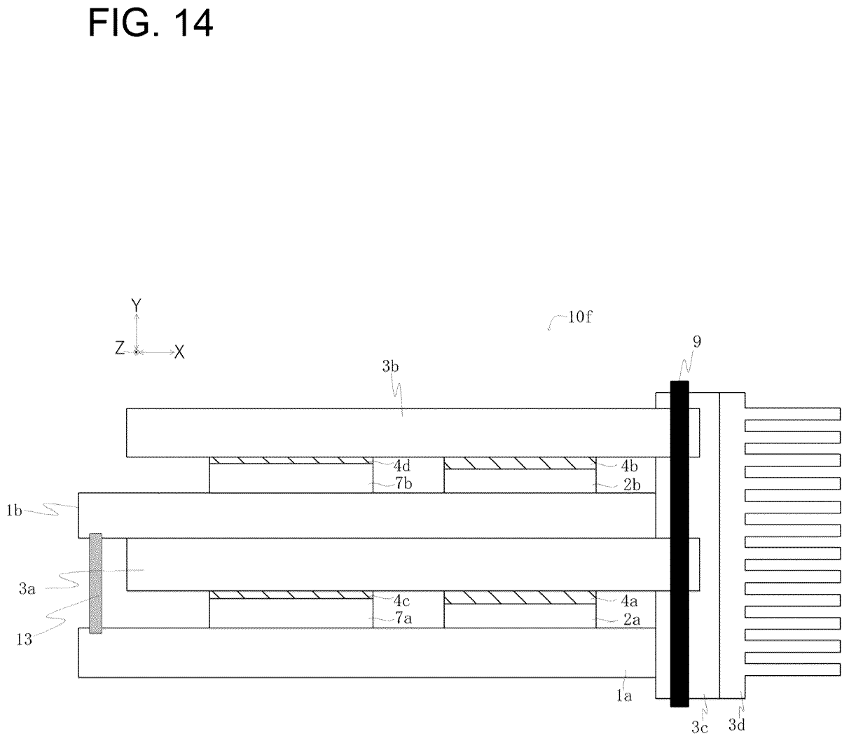

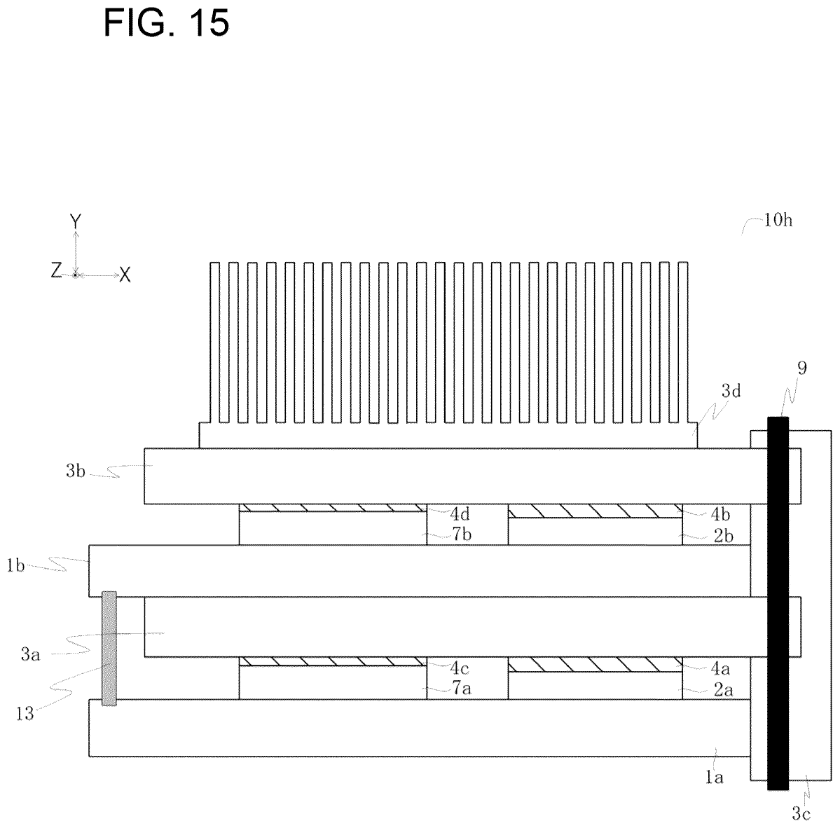

As a modified example 3, FIG. 14 illustrates one aspect of fixing and electrical connecting between the components of the composite module unit according to the present disclosure. A composite module unit 10f in FIG. 14 further includes a heat radiation fin (cooling fin) connected to the third heat dissipation member 3c, in addition to the components of the composite module unit 10e in FIG. 13. Moreover, as a modified example 4, FIG. 15 illustrates one aspect of a method of fixing and electrical connecting between components of the composite module unit according to the present disclosure. A composite module unit 10h in FIG. 15 includes a heat radiation fin 3d connected onto the second heat dissipation member 3b. In accordance with such a configuration, it is possible to suitably cool heat generated in the power element-embedded substrate or the gate driver. The present modified examples illustrate the configuration in which the heat radiation fin is connected to the heat dissipation member 3c or the second heat dissipation member 3b, but the present disclosure is not limited to such a configuration. In the present disclosure, the heat dissipation member 3c or the second heat dissipation member 3b may be connected to a cooler other than the heat radiation fin 3d, for example, to a housing in which the composite module unit is mounted.

### Modified Example 5

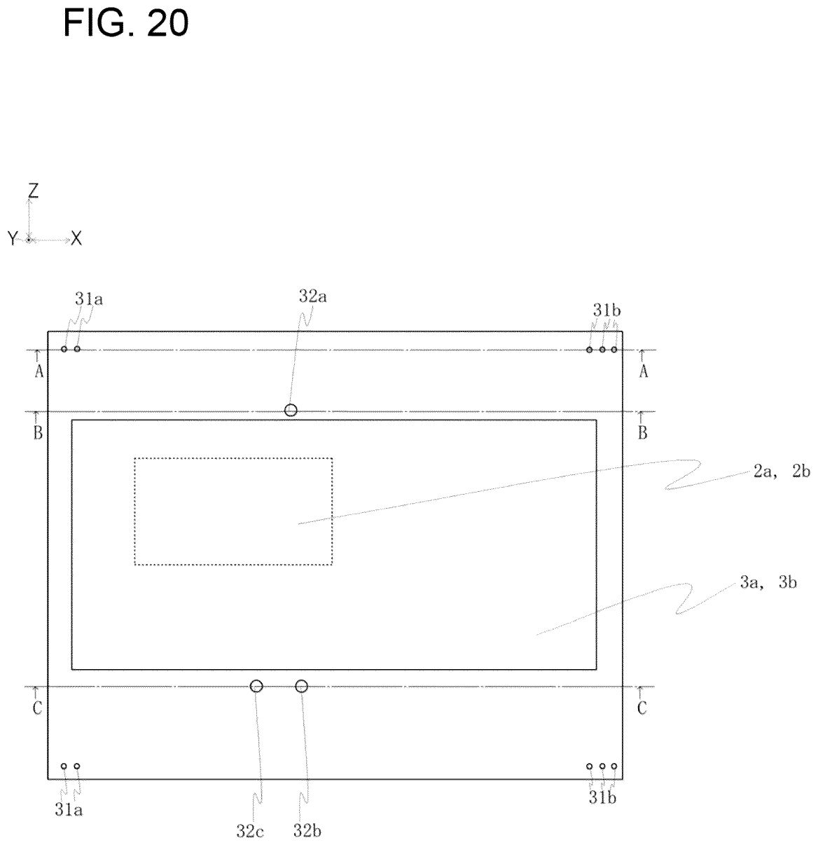

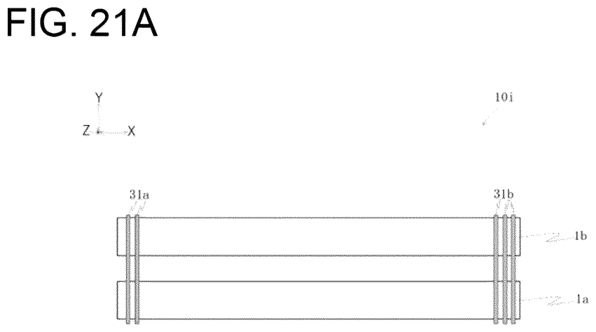

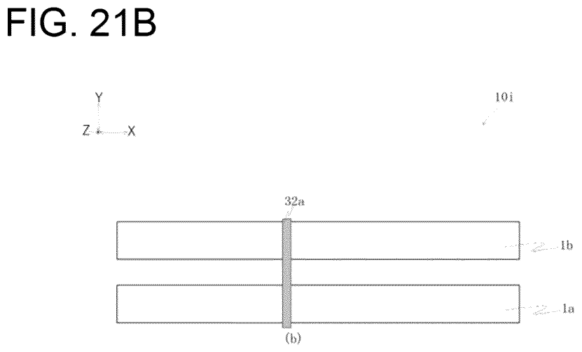

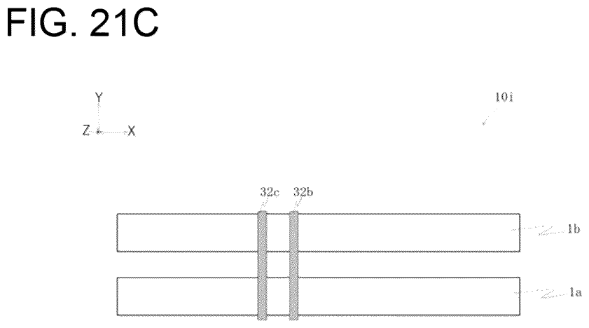

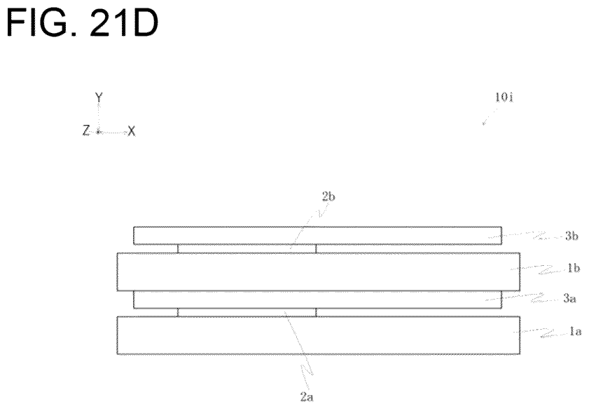

As a modified example 5, with reference to FIGS. 20 to 22, there will now be described one aspect of a method of fixing and electrical connecting between components of the composite module unit according to the present disclosure. FIGS. 20 and 21 are a top view diagram and a cross-sectional diagram schematically illustrating a module unit 10i according to the modified example 5. FIGS. 21A, 21B, 21C, and 21D illustrate respectively cross sections taken along lines A-A, B-B, C-C, and D-D of FIG. 20. As illustrated in FIGS. 20 and 21, an input pin 32a, an output pin 32b, and a GND pin 32c for connecting a power element-embedded substrate of the module unit 10a to a power source, another component, a wiring substrate, and/or a mounting substrate, and power supply pins 31a and signal pins 31b for connecting the other component on the wiring substrate or the wiring substrate to other components, etc. are arranged to pass through the wiring substrate 1a. In the present disclosure, the input pin 32a, the output pin 32b and the GND pin 32c are electrically connected to corresponding electrode pads (signal pads, power supply pads, etc.) on the power element-embedded substrate using wiring patterns or the like, which are not illustrated. In the present disclosure, the input pin 32a, the output pin 32b and the GND pin 32c are preferably located outside and near the outer periphery of the power element-embedded substrate in a plan view (top view).

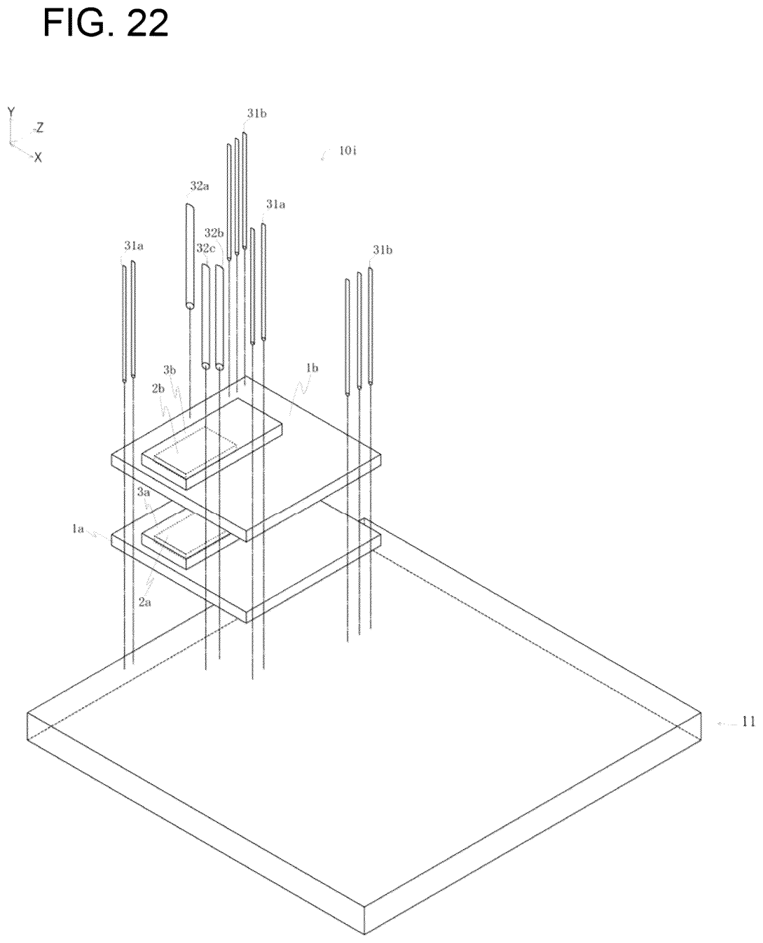

FIG. 22 is an exploded perspective diagram schematically illustrating an example of the module unit 10i in FIGS. 20 and 21 mounted to be stacked on the mounting substrate 11. As illustrated in FIG. 22, the module unit 10i may be mounted so that each electrode pin (the input pin 32a, the output pin 32b, the GND pin 32c, the signal pins 31a, the power supply pins 31b) is inserted into the mounting substrate. In this case, a hole (not illustrated) corresponding to each pin is formed on the mounting substrate 11. The method of mounting the composite module unit 10i on the mounting substrate is not limited to the above-described configuration.

### Modified Example 6

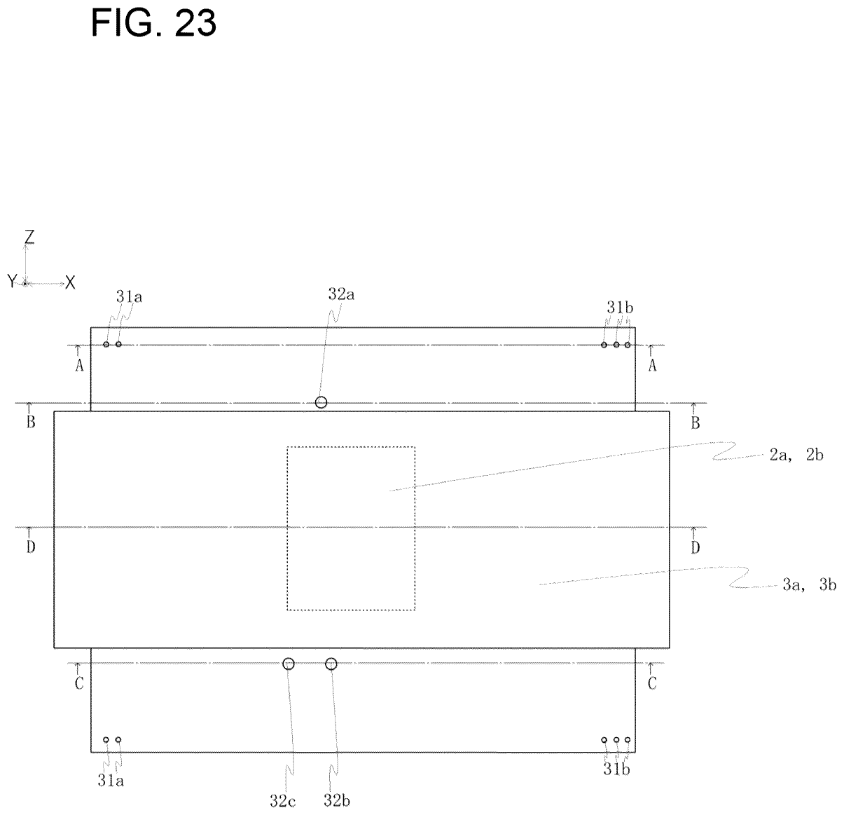

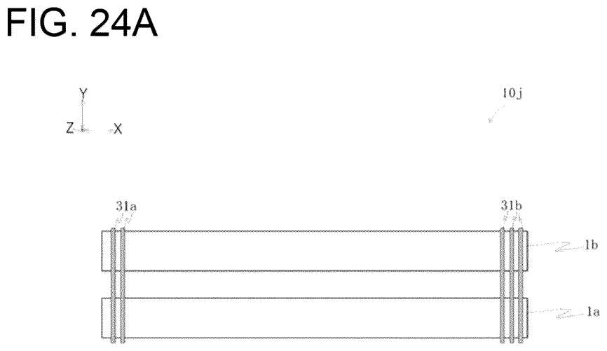

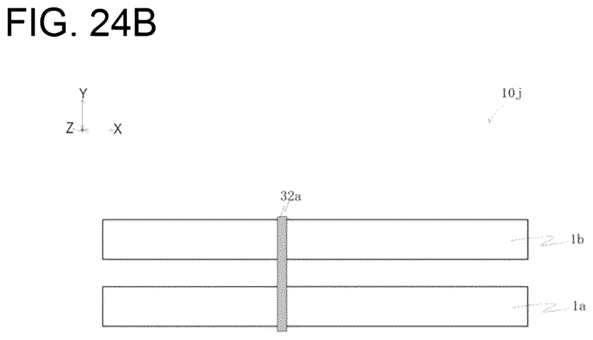

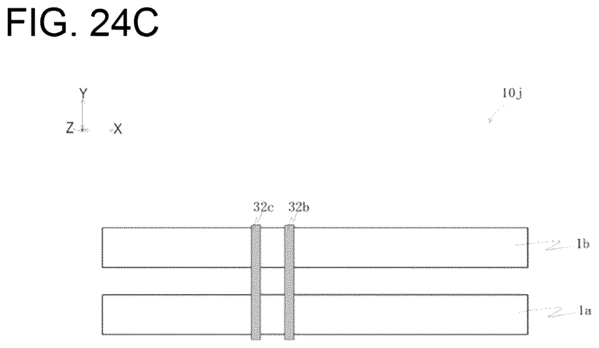

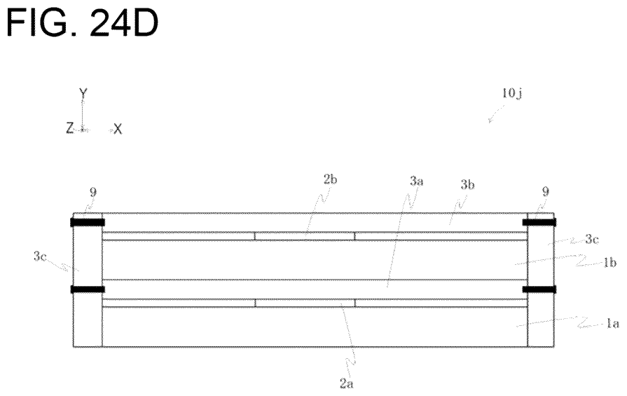

As a modified example 6, with reference to FIGS. 23 and 24, there will now be described one aspect of a method of fixing and electrical connecting between components of the composite module unit according to the present disclosure. FIGS. 23 and 24 are a top view diagram and a cross-sectional diagram schematically illustrating the module unit 10j according to the modified example 6. FIGS. 24A, 24B, 24C, and 24D illustrate respectively cross sections taken along lines A-A, B-B, C-C, and D-D of FIG. 23. The composite module unit 10j illustrated in FIGS. 23 and 24 is different from the composite module unit 10i according to modified example 5 in that the composite module unit 10j has third heat dissipation members 3c on both sides of the first heat dissipation member 3a and the second heat dissipation member 3b. The third heat dissipation member 3c is connected to the first and second heat dissipation members 3a and 3b by using screws 9.

### Modified Example 7

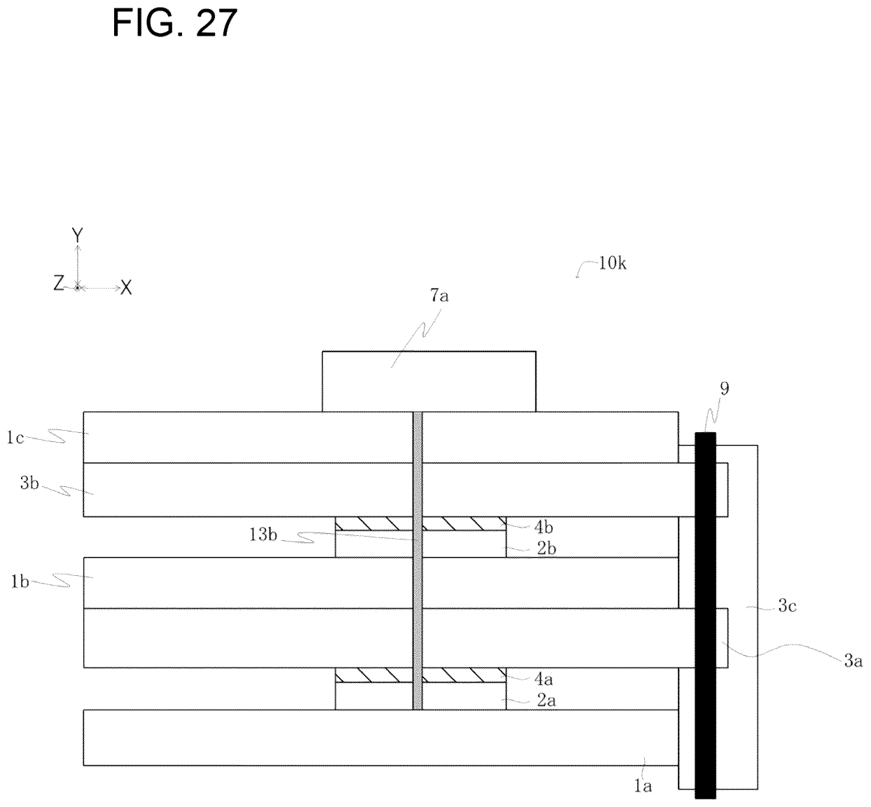

As a modified example 7, FIG. 27 illustrates another aspect of the composite module unit according to the present disclosure. A composite module unit 10k illustrated in FIG. 27 is different from the composite module unit 10d illustrated in FIG. 12 according to the modified example 1 in the following respects: a point of further including a third wiring substrate 1c, and the third wiring substrate 1c being stacked on the second power element-embedded substrate 2b (second heat dissipation member 3b); and a point of the gate driver 7a being mounted on the third wiring substrate 1c. In this modified example 7, the gate driver 7a may control both the first power element-embedded substrate 2a and the second power element-embedded substrate 2b. The gate driver 7a and the power element-embedded substrates 2a and 2b are electrically connected to each other with an electrode pin 13b. In accordance with such a configuration, it is possible to simplify the design of the power element-embedded substrates 2a and 2b and to further reduce the inductance of the gate driver 7a and the power element-embedded substrates 2a and 2b. The fixing method and the electrical connection between the respective components illustrated in FIG. 27 are merely examples, and the present disclosure is not limited to the configurations.

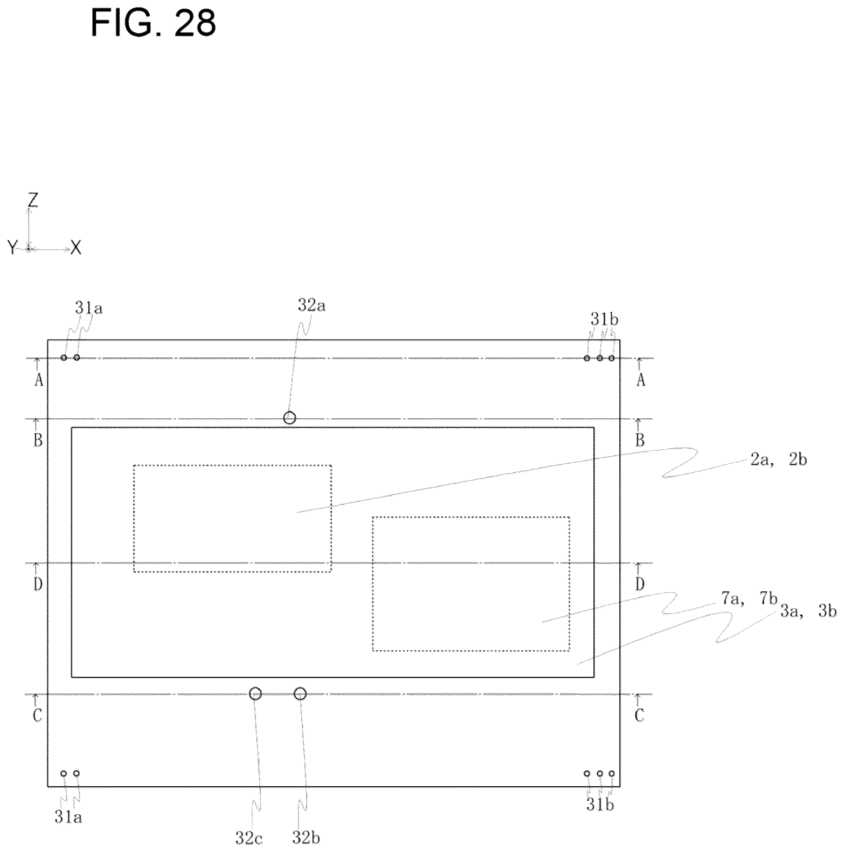

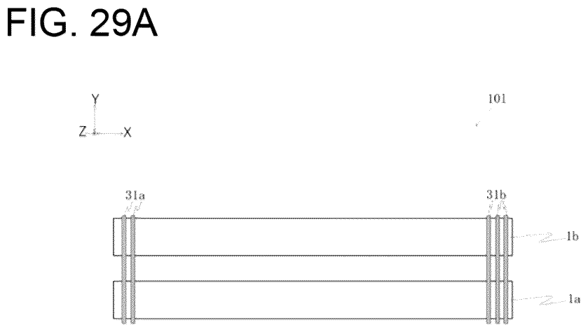

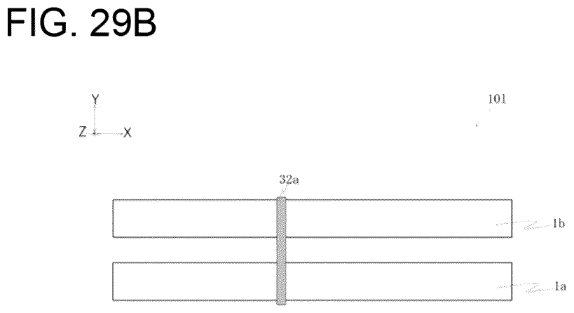

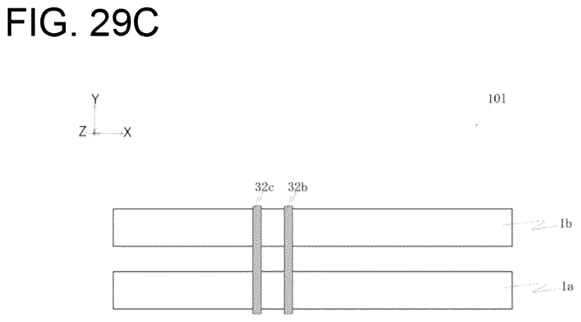

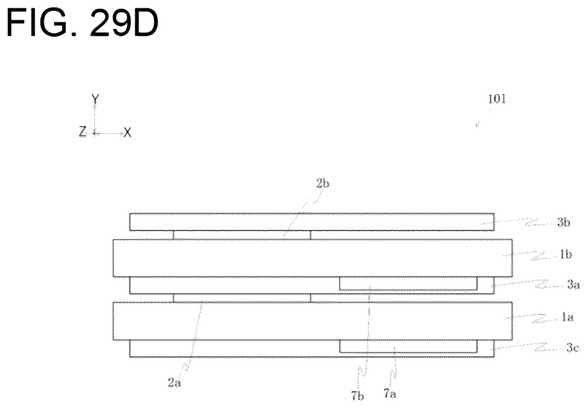

FIGS. 28 and 29 are a top view diagram and a cross-sectional diagram schematically illustrating the module unit 101 according to the modified example 8. FIGS. 29A, 29B, 29C, and 29D illustrate respectively cross sections taken along lines A-A, B-B, C-C, and D-D of FIG. 28. In the module unit 101 in FIG. 28, a heat dissipation member 3a (3c) and a gate driver 7a (7b) for controlling a power element in a power element-embedded substrate 2a (2b) are arranged on a surface side of the wiring substrate opposite to the power element-embedded substrate 2a (2b). According to the module unit 101 illustrated in FIG. 28, since the heat dissipation member (metal block) is arranged on both surfaces of the module unit 101, it is possible to realize a configuration having excellent heat dissipation. Moreover, since the heat dissipation member is disposed also on a back surface side, it is possible to further downsize each heat dissipation member (metal block). Furthermore, according to the module unit 101 in FIG. 28, since the gate driver 7a (7b) is disposed on the back surface side, it is possible to further reduce inductance while minimizing the area of the substrate. Moreover, in the present disclosure, as in the module unit in FIG. 28, the power element-embedded substrate 2a (2b) and the gate driver 7a (7b) may be disposed at positions not overlapping one another in a plan view (when viewed in the Y direction). By arranging in this manner, it is possible to further effectively reduce an influence of heat generated from the power element-embedded substrate 2a (2b) on the gate driver 7a (7b). Alternatively, in the present disclosure, the power element-embedded substrate 2a (2b) and the gate driver 7a (7b) may partly overlap one another in a plan view (when viewed in the Y direction). When an overlapping rate in a plan view is small (e.g., not more than 50% of an area of the power element-embedded substrate, or preferably not more than 30% in a plan view), it is possible to reduce the influence of heat.

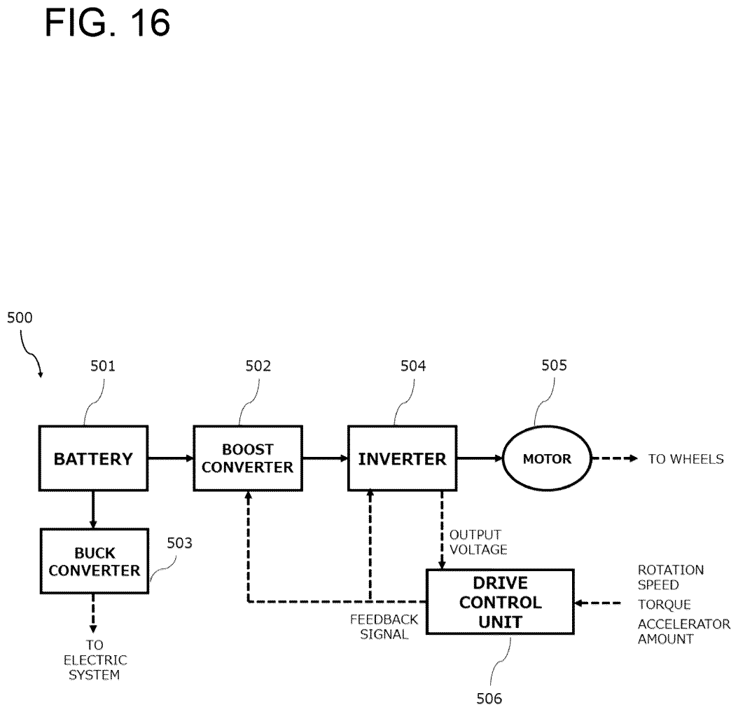

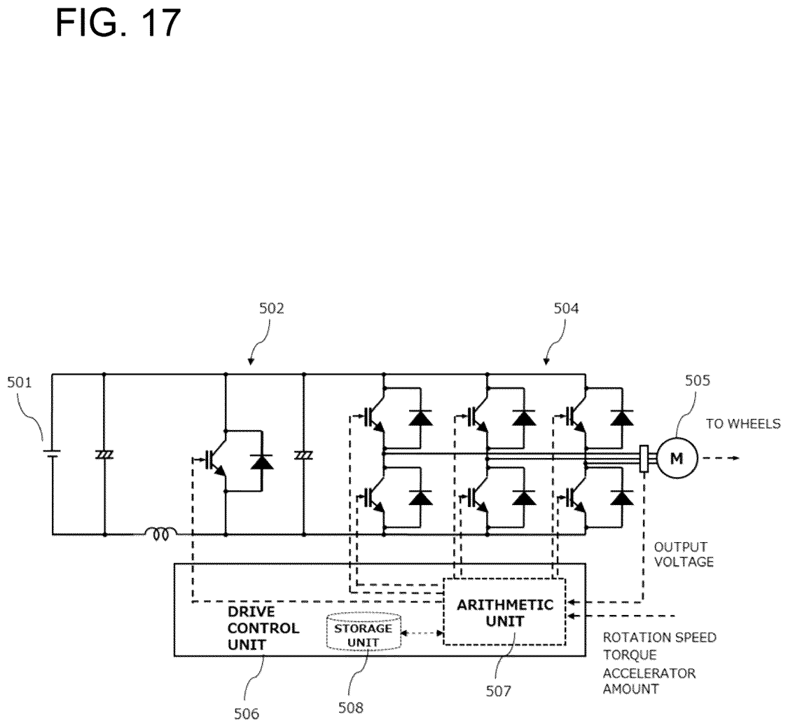

In order to exhibit the functions described above, the composite module unit and/or the system substrate of the disclosure described above may be applied to a power converter such as an inverter or a converter. FIG. 16 is a block diagram illustrating an exemplary control system applying a composite module unit according to an embodiment of the disclosure, and FIG. 17 is a circuit diagram of the control system particularly suitable for applying to a control system of an electric vehicle.

As shown in FIG. 16, the control system 500 includes a battery (power supply) 501, a boost converter 502, a buck converter 503, an inverter 504, a motor (driving object) 505, a drive control unit 506, which are mounted on an electric vehicle. The battery 501 consists of, for example, a storage battery such as a nickel hydrogen battery or a lithium-ion battery. The battery 501 may store electric power by charging at the power supply station or regenerating at the time of deceleration, and to output a direct current (DC) voltage required for the operation of the driving system and the electrical system of the electric vehicle. The boost converter 502 is, for example, a voltage converter in which a chopper circuit is mounted, and may step-up DC voltage of, for example, 200V supplied from the battery 501 to, for example, 650V by switching operations of the chopper circuit. The step-up voltage may be supplied to a traveling system such as a motor. The buck converter 503 is also a voltage converter in which a chopper circuit is mounted, and may step-down DC voltage of, for example, 200V supplied from the battery 501 to, for example, about 12V. The step-down voltage may be supplied to an electric system including a power window, a power steering, or an electric device mounted on a vehicle.

The inverter 504 converts the DC voltage supplied from the boost converter 502 into three-phase alternating current (AC) voltage by switching operations, and outputs to the motor 505. The motor 505 is a three-phase AC motor constituting the traveling system of an electric vehicle, and is driven by an AC voltage of the three-phase output from the inverter 504. The rotational driving force is transmitted to the wheels of the electric vehicle via a transmission mechanism (not shown).

On the other hand, actual values such as rotation speed and torque of the wheels, the amount of depression of the accelerator pedal (accelerator amount) are measured from an electric vehicle in cruising by using various sensors (not shown), The signals thus measured are input to the drive control unit 506. The output voltage value of the inverter 504 is also input to the drive control unit 506 at the same time. The drive control unit 506 has a function of a controller including an arithmetic unit such as a CPU (Central Processing Unit) and a data storage unit such as a memory, and generates a control signal using the inputted measurement signal and outputs the control signal as a feedback signal to the inverters 504, thereby controlling the switching operation by the switching elements. The AC voltage supplied to the motor 505 from the inverter 504 is thus corrected instantaneously, and the driving control of the electric vehicle may be executed accurately. Safety and comfortable operation of the electric vehicle is thereby realized. In addition, it is also possible to control the output voltage to the inverter 504 by providing a feedback signal from the drive control unit 506 to the boost converter 502.

FIG. 17 is a circuit configuration excluding the buck converter 503 in FIG. 16, in other words, a circuit configuration showing a configuration only for driving the motor 505. As shown in the FIG. 17, the composite module unit of the disclosure is provided for switching control by, for example, being applied to the boost controller 502 and the inverter 504 as a Schottky barrier diode. The boost converter 502 performs chopper control by incorporating the semiconductor device into the chopper circuit of the boost converter 502. Similarly, the inverter 504 performs switching control by incorporating the semiconductor device into the switching circuit including an IGBT of the inverter 504. The current may be stabilized by interposing an inductor (such as a coil) at the output of the battery 501. Also, the voltage may be stabilized by interposing a capacitor (such as an electrolytic capacitor) between each of the battery 501, the boost converter 502, and the inverter 504.

As indicated by a dotted line in FIG. 17, an arithmetic unit 507 including a CPU (Central Processing Unit) and a storage unit 508 including a nonvolatile memory are provided in the drive control unit 506. Signal input to the drive control unit 506 is given to the arithmetic unit 507, and a feedback signal for each semiconductor element is generated by performing the programmed operation as necessary. The storage unit 508 temporarily holds the calculation result by the calculation unit 507, stores physical constants and functions necessary for driving control in the form of a table, and outputs the physical constants, functions, and the like to the arithmetic unit 507 as appropriate. The arithmetic unit 507 and the storage unit 508 may be provided by a known configuration, and the processing capability and the like thereof may be arbitrarily selected.

As shown in FIGS. 16 and 17, a diode and a switching element such as a thyristor, a power transistor, an IGBT, a MOSFET and the like is employed for the switching operation of the boost converter 502, the buck converter 503 and the inverter 504 in the control system 500. The use of gallium oxide (Ga2O3) specifically corundum-type gallium oxide (α-Ga2O3) as its materials for these semiconductor devices greatly improves switching properties. Further, extremely outstanding switching performance may be expected and miniaturization and cost reduction of the control system 500 may be realized by applying a composite module unit or a system substrate of the disclosure. That is, each of the boost converter 502, the buck converter 503 and the inverter 504 may be expected to have the benefit of the disclosure, and the effect and the advantages may be expected in any one or combination of the boost converter 502, the buck converter 503 and the inverter 504, or in any one of the boost converter 502, the buck converter 503 and the inverter 504 together with the drive control unit 506.

The control system 500 described above is not only applicable to the control system of an electric vehicle of the composite module unit of the disclosure, but may be applied to a control system for any applications such as to step-up and step-down the power from a DC power source, or convert the power from a DC to an AC. It is also possible to use a power source such as a solar cell as a battery.

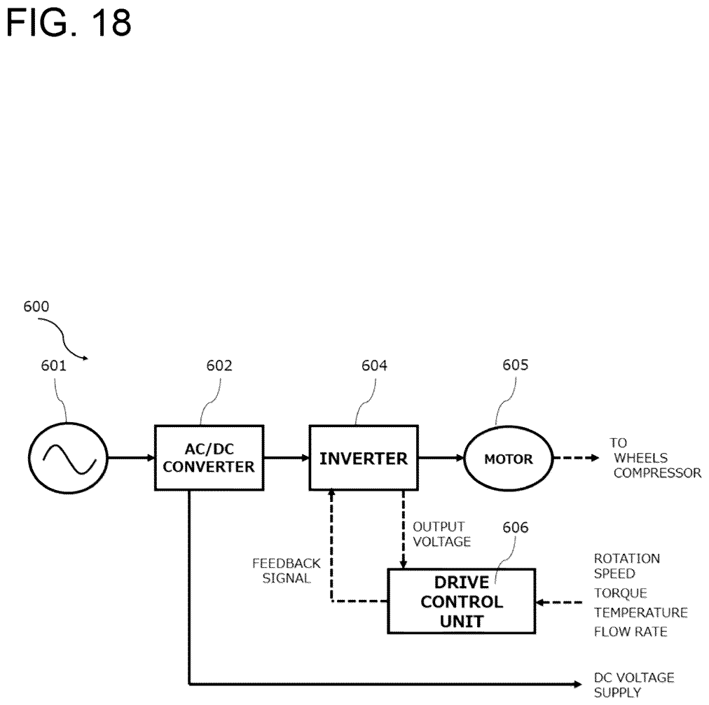

FIG. 18 is a block diagram illustrating another exemplary control system applying a composite module unit according to an embodiment of the disclosure, and FIG. 18 is a circuit diagram of the control system suitable for applying to infrastructure equipment and home appliances or the like operable by the power from the AC power source.

As shown in FIG. 18, the control system 600 is provided for inputting power supplied from an external, such as a three-phase AC power source (power supply) 601, and includes an AC/DC converter 602, an inverter 604, a motor (driving object) 605 and a drive control unit 606 that may be applied to various devices described later. The three-phase AC power supply 601 is, for example, a power plant (such as a thermal, hydraulic, geothermal, or nuclear plant) of an electric power company, whose output is supplied as an AC voltage while being downgraded through substations. Further, the three-phase AC power supply 601 is installed in a building or a neighboring facility in the form of a private power generator or the like for supplying the generated power via a power cable. The AC/DC converter 602 is a voltage converter for converting AC voltage to DC voltage. The AC/DC converter 602 converts AC voltage of 100V or 200V supplied from the three-phase AC power supply 601 to a predetermined DC voltage. Specifically, AC voltage is converted by a transformer to a desired, commonly used voltage such as 3.3V, 5V, or 12V. When the driving object is a motor, conversion to 12V is performed. It is possible to adopt a single-phase AC power supply in place of the three-phase AC power supply. In this case, same system configuration may be realized if an AC/DC converter of the single-phase input is employed.

The inverter 604 converts the DC voltage supplied from the AC/DC converter 602 into three-phase AC voltage by switching operations and outputs to the motor 605. Configuration of the motor 605 is variable depending on the control object. It may be a wheel if the control object is a train, may be a pump and various power source if the control objects a factory equipment, may be a three-phase AC motor for driving a compressor or the like if the control object is a home appliance. The motor 605 is driven to rotate by the three-phase AC voltage output from the inverter 604, and transmits the rotational driving force to the driving object (not shown).

There are many kinds of driving objects such as personal computer, LED lighting equipment, video equipment, audio equipment and the like capable of directly supplying a DC voltage output from the AC/DC converter 602. In that case the inverter 604 becomes unnecessary in the control system 600, and a DC voltage from the AC/DC converter 602 is supplied to the driving object directly as shown in FIG. 18. Here, DC voltage of 3.3V is supplied to personal computers and DC voltage of 5V is supplied to the LED lighting device for example.

On the other hand, rotation speed and torque of the driving object, measured values such as the temperature and flow rate of the peripheral environment of the driving object, for example, is measured using various sensors (not shown), these measured signals are input to the drive control unit 606. At the same time, the output voltage value of the inverter 604 is also input to the drive control unit 606. Based on these measured signals, the drive control unit 606 provides a feedback signal to the inverter 604 thereby controls switching operations by the switching element of the inverter 604. The AC voltage supplied to the motor 605 from the inverter 604 is thus corrected instantaneously, and the operation control of the driving object may be executed accurately. Stable operation of the driving object is thereby realized. In addition, when the driving object may be driven by a DC voltage, as described above, feedback control of the AC/DC converter 602 is possible in place of feedback control of the inverter 604.

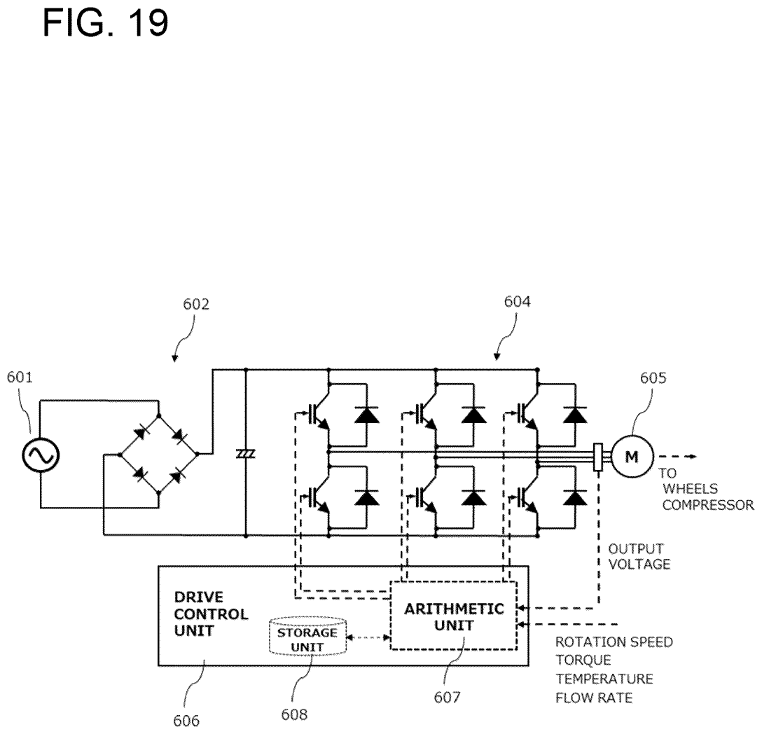

FIG. 19 shows the circuit configuration of FIG. 18. As shown in FIG. 19, the composite module unit of the disclosure is provided for switching control by, for example, being applied to the AC/DC converter 602 and the inverter 604 as a Schottky barrier diode. The AC/DC converter 602 has, for example, a circuit configuration in which Schottky barrier diodes are arranged in a bridge-shaped, to perform a direct-current conversion by converting and rectifying the negative component of the input voltage to a positive voltage. Schottky barrier diodes may also be applied to a switching circuit in IGBT of the inverter 604 to perform switching control. The voltage may be stabilized by interposing a capacitor (such as an electrolytic capacitor) between the AC/DC converter 602 and the inverter 604.

As indicated by a dotted line in FIG. 19, an arithmetic unit 607 including a CPU and a storage unit 608 including a nonvolatile memory are provided in the drive control unit 606. Signal input to the drive control unit 606 is given to the arithmetic unit 607, and a feedback signal for each semiconductor element is generated by performing the programmed operation as necessary. The storage unit 608 temporarily holds the calculation result by the arithmetic unit 607, stores physical constants and functions necessary for driving control in the form of a table, and outputs the physical constants, functions, and the like to the arithmetic unit 607 as appropriate. The arithmetic unit 607 and the storage unit 608 may be provided by a known configuration, and the processing capability and the like thereof may be arbitrarily selected.

In such a control system 600, similarly to the control system 500 shown in FIGS. 16 and 17, a diode or a switching element such as a thyristor, a power transistor, an IGBT, a MOSFET or the like is also applied for the purpose of the rectification operation and switching operation of the AC/DC converter 602 and the inverter 604. Switching performance may be improved by the use of gallium oxide (Ga2O3), particularly corundum-type gallium oxide (α-Ga2O3), as materials for these semiconductor elements. Further, extremely outstanding switching performance may be expected and miniaturization and cost reduction of the control system 600 may be realized by applying a composite module unit or an system substrate of the disclosure. That is, each of the AC/DC converter 602 and the inverter 604 may be expected to have the benefit of the disclosure, and the effects and the advantages of the disclosure may be expected in any one or combination of the AC/DC converter 602 and the inverter 604, or in any of the AC/DC converter 602 and the inverter 604 together with the drive control unit 606.

Although the motor 605 has been exemplified in FIGS. 18 and 19, the driving object is not necessarily limited to those that operate mechanically. Many devices that require an AC voltage may be a driving object. It is possible to apply the control system 600 as long as electric power is obtained from AC power source to drive the driving object. The control system 600 may be applied to the driving control of any electric equipment such as infrastructure equipment (electric power facilities such as buildings and factories, telecommunication facilities, traffic control facilities, water and sewage treatment facilities, system equipment, labor-saving equipment, trains and the like) and home appliances (refrigerators, washing machines, personal computers, LED lighting equipment, video equipment, audio equipment and the like).

### [Additional Note]

As described above, the present embodiments include the following disclosure.

### [Structure 1]

A composite module unit including:

a first module unit including a first wiring substrate and a first power element-embedded substrate mounted on the first wiring substrate; and

a second module unit including a second wiring substrate and a second power element-embedded substrate mounted on the second wiring substrate, the first module unit and the second module unit being stacked in a thickness direction of the first wiring substrate and the second wiring substrate, and being thermally connected to each other via a heat dissipation member.

### [Structure 2]

A composite module unit including:
a first module unit including a first wiring substrate and a first power element-embedded substrate mounted on the first wiring substrate; and
a second module unit including a second wiring substrate and a second power element-embedded substrate mounted on the second wiring substrate,
the first module unit and the second module unit being stacked in a thickness direction of the first wiring substrate and the second wiring substrate,
the composite module unit further including a first heat dissipation member disposed on the first module unit, and a second heat dissipation member disposed along a side surface of the first module unit and a side surface of the second module unit,
the first heat dissipation member and the second heat dissipation member being thermally connected to each other.

### [Structure 3]

The composite module unit according to [Structure 1] or [Structure 2], wherein the first power element-embedded substrate and/or the second power element-embedded substrate include a first wiring layer, a retention layer, an insulation layer located between the first wiring layer and the retention layer, and a power element, wherein the power element is embedded in the insulation layer.

### [Structure 4]

The composite module unit according to [Structure 3], wherein the power element constitutes a portion of a power conversion circuit.

### [Structure 5]

The composite module unit according to any one of [Structure 1] to [Structure 4], further including a gate driver, wherein the gate driver is mounted on at least one of the first wiring substrate and the second wiring substrate.

### [Structure 6]

The composite module unit according to any one of [Structure 1] to [Structure 5], further including a third wiring substrate and a gate driver mounted on the third wiring substrate.

### [Structure 7]

The composite module unit according to any one of [Structure 1] to [Structure 6], wherein the gate driver controls power elements included in the first power element-embedded substrate and the second power element-embedded substrate.

### [Structure 8]

The composite module unit according to any one of [Structure 1] to [Structure 7], wherein the first heat dissipation member is thermally connected to the first wiring substrate.

### [Structure 9]

The composite module unit according to any one of [Structure 1] to [Structure 8], wherein a second heat dissipation member is disposed on the second power element-embedded substrate.

### [Structure 10]

The composite module unit according to any one of [Structure 1] to [Structure 9], wherein the second heat dissipation member is connected to a cooling fin.

### [Structure 11]

The composite module unit according to any one of [Structure 1] to [Structure 10], wherein a third heat dissipation member is disposed on the second power element-embedded substrate, and the third heat dissipation member is thermally connected to the second heat dissipation member.

### [Structure 12]

A system substrate including a module unit and a mounting substrate, the module unit being connected onto the mounting substrate, wherein the module unit is the composite module unit according to [Structure 1] or [Structure 2], and the module unit is longitudinally provided on the mounting substrate.

### [Structure 13]

A system substrate including a module unit and a mounting substrate, the module unit being connected onto the mounting substrate, wherein the module unit is the composite module unit according to [Structure 1] or [Structure 2], and the module unit is connected so that the module unit is stacked on the mounting substrate.

It should be noted that it is naturally possible to combine some or all of the above-described embodiments of the present disclosure, or to apply some of the components to other embodiments, and such combinations and applications also belong to the embodiments of the present disclosure.

### REFERENCE SIGNS LIST

1a First wiring substrate
1b Second wiring substrate
1c Third wiring substrate
2a First power element-embedded substrate
2b Second power element-embedded substrate
3a First heat dissipation member
3b Second heat dissipation member
3c Third heat dissipation member
3d Fourth heat dissipation member (cooler/cooling fin)
4a, 4b Insulating member
4c, 4d Insulating member
5a, 5b Recessed portion
6 Ground electrode
7a First gate driver
7b Second gate driver
8a Electrode pin
8b Hole
10a, 10b, 10c Composite module unit
10d, 10e, 10f Composite module unit
10g, 10h, 10i Composite module unit
10j, 10k, 10l Composite module unit
11 Mounting substrate
12 Passive component
13a Electrode pin
13b Electrode pin
14a Resin portion
14b Pin portion
14c Pin portion
31a Power supply pin
31b Signal pin
32a Input pin
32b Output pin
32c GND pin
101a, 101b Transistor
102a, 102b Diode
111 First wiring layer (upper wiring layer)
112 Retention layer (second wiring layer/lower wiring layer)
115 Insulator
117 Electrical conduction via
118 Base material
119a Insulating protective layer
119b Insulating protective layer
120 Through hole
111a Adhesion layer (conductive adhesion layer)
111b Adhesion layer (conductive adhesion layer)
500 Control system
501 Battery (power source)
502 Boost converter
503 Buck converter
504 Inverter
505 Motor (to be driven)
506 Drive control unit
507 Calculation unit
508 Storage unit
600 Control system
601 Three-phase alternating current power source (power source)
602 AC/DC converter
604 Inverter
605 Motor (to be driven)
606 Drive control unit
607 Calculation unit
608 Storage unit

What is claimed is:

1. A composite module unit comprising:
a first module unit including a first wiring substrate and a first power element-embedded substrate mounted on the first wiring substrate; and
a second module unit including a second wiring substrate and a second power element-embedded substrate mounted on the second wiring substrate,
the first module unit and the second module unit being stacked in a thickness direction of the first wiring substrate and the second wiring substrate, and being thermally connected to each other via a heat dissipation member.

2. A composite module unit comprising:
a first module unit including a first wiring substrate and a first power element-embedded substrate mounted on the first wiring substrate; and
a second module unit including a second wiring substrate and a second power element-embedded substrate mounted on the second wiring substrate,
the first module unit and the second module unit being stacked in a thickness direction of the first wiring substrate and the second wiring substrate,
the composite module unit further including a first heat dissipation member disposed on the first module unit, and a second heat dissipation member disposed along a side surface of the first module unit and a side surface of the second module unit,
the first heat dissipation member and the second heat dissipation member being thermally connected to each other.

3. The composite module unit according to claim 1, wherein the first power element-embedded substrate and/or the second power element-embedded substrate comprise a first wiring layer, a retention layer, an insulation layer located between the first wiring layer and the retention layer, and a power element, wherein the power element is embedded in the insulation layer.

4. The composite module unit according to claim 3, wherein the power element constitutes a portion of a power conversion circuit.

5. The composite module unit according to claim 1, further comprising a gate driver, wherein the gate driver is mounted on at least one of the first wiring substrate and the second wiring substrate.

6. The composite module unit according to claim 1, further comprising a third wiring substrate and a gate driver mounted on the third wiring substrate.

7. The composite module unit according to claim 6, wherein the gate driver controls power elements included in the first power element-embedded substrate and the second power element-embedded substrate.

8. The composite module unit according to claim 2, wherein the first heat dissipation member is thermally connected to the first wiring substrate.

9. The composite module unit according to claim 1, wherein a second heat dissipation member is disposed on the second power element-embedded substrate.

10. The composite module unit according to claim 9, wherein the second heat dissipation member is connected to a cooling fin.

11. The composite module unit according to claim 2, wherein a third heat dissipation member is disposed on the second power element-embedded substrate, and the third heat dissipation member is thermally connected to the second heat dissipation member.

12. A system substrate comprising a module unit and a mounting substrate, the module unit being connected onto the mounting substrate, wherein the module unit is the composite module unit according to claim 1, and the module unit is longitudinally provided on the mounting substrate.

13. A system substrate comprising a module unit and a mounting substrate, the module unit being connected onto the mounting substrate, wherein the module unit is the composite module unit according to claim 1, and the module unit is connected so that the module unit is stacked on the mounting substrate.
